(19) United States
(12) Patent Application Publication
(10) Pub. No.: US 2025/0176155 A1
(43) Pub. Date: May 29, 2025

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Tatsuya ONUKI, Atsugi, Kanagawa (JP); Hitoshi KUNITAKE, Machida, Tokyo (JP); Motoki NAKASHIMA, Atsugi, Kanagawa (JP)

(21) Appl. No.: 18/859,601

(22) PCT Filed: Apr. 14, 2023
(86) PCT No.: PCT/IB2023/053816

§ 371 Date: Oct. 24, 2024

(30) Foreign Application Priority Data
Apr. 28, 2022 (JP) 2022-075007

(51) Int. Cl. H10B 12/00

(52) U.S. Cl. CPC H10B 12/00

(57) ABSTRACT

A semiconductor device that can be miniaturized or highly integrated is provided. The semiconductor device includes a first conductor, a second conductor over the first conductor, a third conductor in contact with a top surface of the second conductor, a fourth conductor over the third conductor, a fifth conductor over the second conductor and the fourth conductor, first and second oxides, and fourth and fifth insulators. The fourth insulator and the first oxide are placed inside a first opening provided in the fourth conductor and the like; the first oxide includes a region facing the fourth conductor with the fourth insulator therebetween, a region in contact with a top surface of the third conductor, and a region in contact with a bottom surface of the fifth conductor. The fifth insulator and the second oxide are placed inside a second opening provided in the second conductor and the like; the second oxide includes a region facing the second conductor with the fifth insulator therebetween, a region in contact with a top surface of the first conductor, and a region in contact with the bottom surface of the fifth conductor.

### TECHNICAL FIELD

One embodiment of the present invention relates to a semiconductor device, a storage device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting apparatus, a power storage device, a storage device, an electronic device, a lighting device, an input device (e.g., a touch sensor), an input/output device (e.g., a touch panel), a method for driving any of them, and a method of manufacturing any of them.

In this specification and the like, a semiconductor device generally means a device that can function by utilizing semiconductor characteristics. A semiconductor element such as a transistor, a semiconductor circuit, an arithmetic device, and a storage device are each one embodiment of a semiconductor device. It can sometimes be said that a display device (a liquid crystal display device, a light-emitting display device, and the like), a projection device, a lighting device, an electro-optical device, a power storage device, a storage device, a semiconductor circuit, an imaging device, an electronic device, and the like include a semiconductor device.

### BACKGROUND ART

In recent years, semiconductor devices such as an LSI (Large Scale Integration), a CPU (Central Processing Unit), and a memory (storage device) have been developed. These semiconductor devices have been used in various electronic devices such as computers and portable information terminals. In addition, memories under development employ various memory systems for intended uses such as temporary storage at the time of executing arithmetic processing and long-term storage of data. Memories with typical memory systems include a DRAM (Dynamic Random Access Memory), an SRAM (Static Random Access Memory), and a flash memory.

With the increase in the amount of data dealt with, semiconductor devices having a larger memory capacity have been required. Patent Document 1 and Non-Patent Document 1 disclose memory cells in which transistors are stacked.

In order to increase the memory capacity of the semiconductor device, miniaturization of transistors included in the semiconductor device has been promoted. To miniaturize the transistors, a transistor having a vertical structure has been actively studied. For example, Non-Patent Document 2 and Non-Patent Document 3 disclose a transistor having a vertical structure including a metal oxide in a region where a channel is formed (also referred to as a channel formation region).

### REFERENCES

### Patent Document

[Patent Document 1] PCT International Publication No. 2021/053473

### Non-Patent Documents

[Non-Patent Document 1] M. Oota, et al., “3D-Stacked CAAC-In—Ga—Zn Oxide FETs with Gate Length of 72 nm”, IEDM Tech. Dig., 2019, pp. 50-53
[Non-Patent Document 2] X. Duan et al., “Novel Vertical Channel-All-Around (CAA) IGZO FETs for 2T0C DRAM with High Density beyond 4 F² by Monolithic Stacking”, IEDM Tech. Dig., 2021, pp. 222-225
[Non-Patent Document 3] H. Fujiwara et al., “Surrounding Gate Vertical-Channel FET with Gate Length of 40 nm Using BEOL Compatible High-Thermal-Tolerance In—Al—Zn Oxide Channel”, 2020 Symposium on VLSI Technology, TH2.2

### SUMMARY OF THE INVENTION

### Problems to be Solved by the Invention

An object of one embodiment of the present invention is to provide a semiconductor device that can be miniaturized or highly integrated. Another object of one embodiment of the present invention is to provide a semiconductor device with high operating speed. Another object of one embodiment of the present invention is to provide a semiconductor device having favorable electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device.

Another object of one embodiment of the present invention is to provide a storage device having large memory capacity. Another object of one embodiment of the present invention is to provide a storage device occupying a small area. Another object of one embodiment of the present invention is to provide a highly reliable storage device. Another object of one embodiment of the present invention is to provide a storage device with low power consumption. Another object of one embodiment of the present invention is to provide a novel storage device.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a semiconductor device including a first conductor; a first insulator over the first conductor; a second conductor over the first insulator; a third conductor over the second conductor; a second insulator over the first insulator, the second conductor, and the third conductor; a fourth conductor over the second insulator; a third insulator over the fourth conductor; a fifth conductor over the third insulator; a first oxide; a second oxide; a fourth insulator; and a fifth insulator. A first opening reaching the third conductor is provided in the second insulator, the fourth conductor, and the third insulator. The fourth insulator includes a region in contact with a side surface of the fourth conductor in the first opening. The first oxide includes a region facing the fourth conductor with the fourth insulator therebetween, a region in contact with at least part of a top surface of the third conductor, and a region in contact with at least part of a bottom surface of the fifth conductor. A second opening reaching the first conductor is provided in the first insulator, the second conductor, the second insulator, and the third insulator. The fifth insulator includes a region in contact with a side surface of the second conductor in the second opening. The second oxide includes a region facing the second conductor with the fifth insulator therebetween, a region in contact with at least part of a top surface of the first conductor, and a region in contact with at least part of the bottom surface of the fifth conductor.

In the above semiconductor device, a direction in which the fourth conductor extends is preferably parallel to a direction in which the first conductor extends.

In the above semiconductor device, a diameter of the second opening is preferably larger than a diameter of the first opening in a plan view.

In a cross-sectional view of the above semiconductor device, a sidewall of the first opening and a sidewall of the second opening each preferably have a tapered shape.

One embodiment of the present invention is a semiconductor device including a first insulator; a first conductor and a second conductor over the first insulator; a second insulator over the first insulator, the first conductor, and the second conductor; a third conductor over the second insulator; a fourth conductor over the third conductor; a third insulator over the second insulator, the third conductor, and the fourth conductor; a fifth conductor over the third insulator; a fourth insulator over the fifth conductor; a sixth conductor over the fourth insulator; a first oxide; a second oxide; a fifth insulator; and a sixth insulator. The first conductor includes a region overlapping with the third conductor with the second insulator therebetween. A first opening reaching the fourth conductor is provided in the third insulator, the fifth conductor, and the fourth insulator. The fifth insulator includes a region in contact with a side surface of the fifth conductor in the first opening. The first oxide includes a region facing the fifth conductor with the fifth insulator therebetween, a region in contact with at least part of a top surface of the fourth conductor, and a region in contact with at least part of a bottom surface of the sixth conductor. A second opening reaching the second conductor is provided in the second insulator, the third conductor, the third insulator, and the fourth insulator. The sixth insulator includes a region in contact with a side surface of the third conductor in the second opening. The second oxide includes a region facing the third conductor with the sixth insulator therebetween, a region in contact with at least part of a top surface of the second conductor, and a region in contact with at least part of the bottom surface of the sixth conductor.

In the above semiconductor device, a direction in which the first conductor extends is preferably parallel to a direction in which the second conductor extends. A direction in which the fifth conductor extends is preferably parallel to the direction in which the second conductor extends.

In the above semiconductor device, the first conductor and the second conductor are preferably provided in the same layer.

One embodiment of the present invention is a semiconductor device including a first insulator; a first conductor and a second conductor over the first insulator; a second insulator over the first insulator, the first conductor, and the second conductor; a third conductor over the second insulator; a fourth conductor over the third conductor; a third insulator over the second insulator, the third conductor, and the fourth conductor; a fifth conductor over the third insulator; a fourth insulator over the fifth conductor; a sixth conductor and a seventh conductor over the fourth insulator; a first oxide; a second oxide; a fifth insulator; and a sixth insulator. The first conductor includes a region overlapping with the third conductor with the second insulator therebetween. A first opening reaching the fourth conductor is provided in the third insulator, the fifth conductor, and the fourth insulator. The fifth insulator includes a region in contact with a side surface of the fifth conductor in the first opening. The first oxide includes a region facing the fifth conductor with the fifth insulator therebetween, a region in contact with at least part of a top surface of the fourth conductor, and a region in contact with at least part of a bottom surface of the sixth conductor. A second opening reaching the second conductor is provided in the second insulator, the third conductor, the third insulator, and the fourth insulator. The sixth insulator includes a region in contact with a side surface of the third conductor in the second opening. The second oxide includes a region facing the third conductor with the sixth insulator therebetween, a region in contact with at least part of a top surface of the second conductor, and a region in contact with at least part of a bottom surface of the seventh conductor.

In the above semiconductor device, a direction in which the first conductor extends is preferably parallel to a direction in which the second conductor extends. A direction in which the fifth conductor extends is preferably parallel to the direction in which the second conductor extends. A direction in which the sixth conductor extends is preferably parallel to a direction in which the seventh conductor extends.

In the above semiconductor device, the first conductor and the second conductor are preferably provided in the same layer. The sixth conductor and the seventh conductor are preferably provided in the same layer.

In the above semiconductor device, the metal oxide preferably includes two or three selected from indium, an element M, and zinc. The element M is preferably one or more kinds selected from aluminum, gallium, yttrium, and tin.

### Effect of the Invention

According to one embodiment of the present invention, a semiconductor device that can be miniaturized or highly integrated can be provided. According to one embodiment of the present invention, a semiconductor device with high operating speed can be provided. According to one embodiment of the present invention, a semiconductor device having favorable electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with a high on-state current can be provided. According to one embodiment of the present invention, a semiconductor device with low power consumption can be provided. According to one embodiment of the present invention, a novel semiconductor device can be provided.

According to one embodiment of the present invention, a storage device having large memory capacity can be provided. According to one embodiment of the present invention, a storage device occupying a small area can be provided. According to one embodiment of the present invention, a highly reliable storage device can be provided. According to one embodiment of the present invention, a storage device with low power consumption can be provided. According to one embodiment of the present invention, a novel storage device can be provided.

Note that the description of these effects does not preclude the presence of other effects. One embodiment of the present invention does not necessarily have all the effects. Other effects can be derived from the description of the specification, the drawings, and the claims.

### BRIEF DESCRIPTION OF THE DRAWINGS

FIG. 1A is a perspective view illustrating a structure example of a semiconductor device. FIG. 1B is a top view illustrating the structure example of the semiconductor device.

FIG. 2A is atop view illustrating a structure example of a semiconductor device. FIG. 2B to FIG. 2D are cross-sectional views illustrating the structure example of the semiconductor device. FIG. 2E is a circuit diagram for describing a structure of the semiconductor device.

FIG. 3A is atop view illustrating a structure example of a semiconductor device. FIG. 3B to FIG. 3D are cross-sectional views illustrating the structure example of the semiconductor device.

FIG. 4A is atop view illustrating a structure example of a semiconductor device. FIG. 4B to FIG. 4D are cross-sectional views illustrating the structure example of the semiconductor device.

FIG. 5A is atop view illustrating a structure example of a semiconductor device. FIG. 5B to FIG. 5D are cross-sectional views illustrating the structure example of the semiconductor device.

FIG. 6A is atop view illustrating a structure example of a semiconductor device. FIG. 6B to FIG. 6D are cross-sectional views illustrating the structure example of the semiconductor device.

FIG. 7A is atop view illustrating a structure example of a semiconductor device. FIG. 7B to FIG. 7D are cross-sectional views illustrating the structure example of the semiconductor device.

FIG. 8A and FIG. 8B are top views illustrating structure examples of a semiconductor device.

FIG. 9A is atop view illustrating a structure example of a semiconductor device. FIG. 9B to FIG. 9D are cross-sectional views illustrating the structure example of the semiconductor device. FIG. 9E is a circuit diagram for describing a structure of the semiconductor device.

FIG. 10A is a top view illustrating a structure example of a semiconductor device. FIG. 10B to FIG. 10D are cross-sectional views illustrating the structure example of the semiconductor device. FIG. 10E is a circuit diagram for describing a structure of the semiconductor device.

FIG. 11A is a top view illustrating a structure example of a semiconductor device. FIG. 11B to FIG. 11D are cross-sectional views illustrating the structure example of the semiconductor device.

FIG. 12A is a top view illustrating a structure example of a semiconductor device. FIG. 12B to FIG. 12D are cross-sectional views illustrating the structure example of the semiconductor device. FIG. 12E is a circuit diagram for describing a structure of the semiconductor device.

FIG. 13A is a top view illustrating a structure example of a semiconductor device. FIG. 13B to FIG. 13D are cross-sectional views illustrating the structure example of the semiconductor device. FIG. 13E is a circuit diagram for describing a structure of the semiconductor device.

FIG. 14A, FIG. 14C, and FIG. 14E are top views illustrating an example of a method for manufacturing a semiconductor device. FIG. 14B, FIG. 14D, and FIG. 14F are cross-sectional views illustrating the example of the method for manufacturing a semiconductor device.

FIG. 15A and FIG. 15C are top views illustrating an example of a method for manufacturing a semiconductor device. FIG. 15B and FIG. 15D are cross-sectional views illustrating the example of the method for manufacturing a semiconductor device.

FIG. 16A and FIG. 16C are top views illustrating an example of a method for manufacturing a semiconductor device. FIG. 16B and FIG. 16D are cross-sectional views illustrating the example of the method for manufacturing a semiconductor device.

FIG. 17A is a block diagram illustrating a structure example of a storage device. FIG. 17B is a perspective view illustrating a structure example of a storage device.

FIG. 18A to FIG. 18E are circuit diagrams illustrating structure examples of memory cells. FIG. 18F and FIG. 18G are perspective views illustrating a structure example of a storage device.

FIG. 19 is a cross-sectional view illustrating a structure example of a storage device.

FIG. 20 is a cross-sectional view illustrating a structure example of a storage device.

FIG. 21A to FIG. 21E are diagrams for describing examples of storage devices.

FIG. 22A and FIG. 22B are diagrams illustrating examples of electronic components.

FIG. 23A and FIG. 23B illustrate examples of electronic devices, and FIG. 23C to FIG. 23E illustrate an example of a large computer.

FIG. 24 is a diagram illustrating an example of space equipment.

FIG. 25 is a diagram illustrating an example of a storage system that can be used in a data center.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. Note that the drawings schematically show ideal examples, and embodiments of the present invention are not limited to shapes, values, or the like shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is used for portions having similar functions, and the portions are not especially denoted by reference numerals in some cases.

In particular, in a perspective view, a top view (also referred to as a “plan view”), or the like, some components may not be illustrated for easy understanding of the invention. In addition, the description of some hidden lines and the like may be omitted. In the drawings, for example, a hatching pattern or the like may be omitted. Furthermore, a hatching pattern for one component is different between a top view and a cross-sectional view in some cases.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

Note that the term “film” and the term “layer” can be used interchangeably depending on the case or the situation. For example, the term “conductive layer” can be replaced with the term “conductive film”. For another example, the term “insulating film” can be replaced with the term “insulating layer”.

In this specification and the like, the term “insulator” can be replaced with an insulating film or an insulating layer. Furthermore, the term “conductor” can be replaced with a conductive film or a conductive layer. Moreover, the term “semiconductor” can be replaced with a semiconductor film or a semiconductor layer.

Note that in this specification and the like, an oxynitride refers to a material in which the oxygen content is higher than the nitrogen content, and a nitride oxide refers to a material in which the nitrogen content is higher than the oxygen content. For example, silicon oxynitride refers to a material in which the oxygen content is higher than the nitrogen content, and silicon nitride oxide refers to a material in which the nitrogen content is higher than the oxygen content.

In this specification and the like, terms for describing positioning, such as “over”, “under”, “above”, and “below”, are sometimes used for convenience to describe the positional relationship between components with reference to drawings. The positional relationship between components is changed as appropriate in accordance with a direction in which each component is described. Thus, the positional relationship is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

In this specification and the like, the expression “level with” indicates a structure having the same level from a reference surface (e.g., a flat surface such as a substrate surface) in the cross-sectional view. For example, in a manufacturing process of a semiconductor device, planarization treatment (typically, chemical mechanical polishing (CMP) treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as “level with” in this specification and the like. For example, the expression “level with” includes the case where two layers (here, given as a first layer and a second layer) whose levels with respect to the reference surface are different from each other are included, and the difference between the top-surface level of the first layer and the top-surface level of the second layer is less than or equal to 20 nm.

In this specification and the like, the expression “end portions are aligned” means that at least outlines of stacked layers partly overlap with each other in the top view. For example, the case of processing the upper layer and the lower layer with use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned”.

In general, it is difficult to clearly differentiate “perfectly aligned” from “substantially aligned”. In this specification, the expression “aligned” includes both “perfectly aligned” and “substantially aligned”.

In this specification and the like, the expression “parallel” indicates a state where two straight lines are placed at an angle greater than or equal to −10° and less than or equal to 10°. Accordingly, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, the expression “perpendicular” indicates a state where two straight lines are placed at an angle greater than or equal to 80° and less than or equal to 100°. Accordingly, the case where the angle is greater than or equal to 85° and less than or equal to 95° is also included. Furthermore, the expression “substantially perpendicular” indicates a state where two straight lines are placed at an angle greater than or equal to 60° and less than or equal to 120°.

### Embodiment 1

In this embodiment, a semiconductor device of one embodiment of the present invention and a manufacturing method of the semiconductor device are described with reference to drawings.

One embodiment of the present invention relates to a semiconductor device provided over a substrate. The semiconductor device includes a first transistor and a second transistor, which can form a memory cell. The semiconductor device of one embodiment of the present invention includes the memory cell and thus has a function of storing data. Therefore, the semiconductor device of one embodiment of the present invention can be referred to as a storage device. Note that the semiconductor device of one embodiment of the present invention may further include a capacitor, or may further include a third transistor and a capacitor.

The semiconductor device of one embodiment of the present invention preferably includes a transistor containing an oxide semiconductor in a channel formation region (an OS transistor). The OS transistor has a low off-state current. Thus, by including an OS transistor, the semiconductor device capable of serving as a storage device can retain stored contents for a long time. That is, a refresh operation is not required or the frequency of the refresh operation is extremely low; thus, the power consumption of the semiconductor device can be adequately reduced. Thus, a semiconductor device with low power consumption can be provided. An OS transistor has high frequency characteristics and thus the semiconductor device can perform data reading and data writing at high speed. Thus, a semiconductor device with high operating speed can be provided.

In each of the first transistor and the second transistor, one of a source electrode and a drain electrode is positioned below and the other is positioned above; thus, current flows in the vertical direction. In other words, the channel length direction of each of the first transistor and the second transistor is the vertical direction. That is, the first transistor and the second transistor are transistors each having a vertical structure. A transistor having a vertical structure can be miniaturized as compared with a transistor having what is called a horizontal structure in which current flows in the horizontal direction. Accordingly, the first transistor and the second transistor each having a vertical structure can be placed at high density and thus high integration of the semiconductor device can be achieved. In addition, a transistor having a vertical structure can have a larger channel width per unit area than a transistor having a horizontal structure. Thus, the density of current flowing through the transistor becomes high, so that the on-state current of the transistor can be increased and the frequency characteristics can be improved.

An OS transistor has high resistance to a short-channel effect. Accordingly, as compared with a transistor containing silicon in a channel formation region (also referred to as a Si transistor), an OS transistor is hardly affected by a substrate floating effect even with a vertical structure, and can easily have a short channel length even with a thick gate insulating film. That is, a gate leakage current can be reduced, so that the storage device can have improved retention characteristics.

The short-channel effect refers to degradation of electrical characteristics which becomes obvious along with miniaturization of a transistor (a decrease in channel length). Examples of the short-channel effect include drain-induced barrier lowering, electron velocity saturation, and hot-carrier degradation. Specific examples of the short-channel effect include a decrease in threshold voltage, an increase in subthreshold swing value, and an increase in leakage current. Here, the subthreshold swing value means the amount of change in gate voltage in the subthreshold region when the drain voltage keeps constant and the drain current changes by one order of magnitude.

The channel length of a transistor having a vertical structure can be controlled by the thickness of a film provided between a source electrode and a drain electrode, so that a processing variation in the channel length can be smaller than that of a transistor having a horizontal structure. That is, a variation in the density of current flowing through the transistor can be suppressed. Thus, the frequency characteristics can be improved.

In the case where a memory cell is formed using the first transistor and the second transistor, one of the first transistor and the second transistor functions as a write transistor and the other of the first transistor and the second transistor functions as a read transistor. A read transistor preferably has high on-state current characteristics. A write transistor preferably has low off-state current characteristics. Thus, to manufacture a high-performance storage device, it is desired to form transistors having required different characteristics. In each of the first transistor and the second transistor that are transistors each having a vertical structure, the channel width related to the on-state current of the transistor can be adjusted by the size (also referred to as diameter) in the plan view (also referred to as the top view) of an opening provided with part of components of the transistor. Thus, the opening provided with part of components of the first transistor and the opening provided with part of components of the second transistor are different from each other, whereby a storage device with excellent performance can be manufactured.

The semiconductor device of one embodiment of the present invention has a structure in which one of the source electrode and the drain electrode of the first transistor is directly connected to a gate electrode of the second transistor. Accordingly, it is not necessary to provide an electrode for connecting one of the source electrode and the drain electrode of the first transistor and the gate electrode of the second transistor; thus, the memory cell can be formed without reducing transistor density. Therefore, the memory cell can have a high degree of integration and large memory capacity. Moreover, the number of steps in the manufacturing process of the semiconductor device can be reduced.

### <Structure Example of Semiconductor Device>

Structure examples of a semiconductor device of one embodiment of the present invention will be described below. Note that components of the semiconductor device of this embodiment may each have either a single-layer structure or a stacked-layer structure.

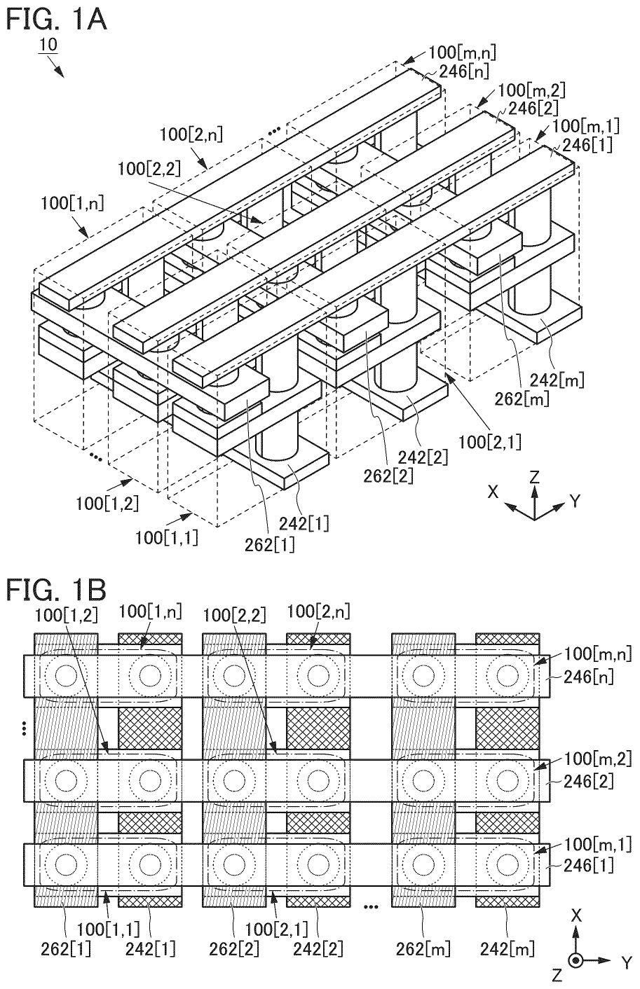

FIG. 1A and FIG. 1B are a perspective view and a top view illustrating a structure example of the semiconductor device of one embodiment of the present invention. FIG. 1A is a perspective view of a semiconductor device 10. FIG. 1B is a top view of the semiconductor device 10.

Note that in the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device 10 includes a plurality of memory cells 100. FIG. 1A illustrates an example of the semiconductor device 10 including the plurality of memory cells 100 arranged in a matrix of m rows and n columns (m and n are each independently an integer greater than or equal to 2). A memory cell array can be formed when the memory cells 100 are arranged in a matrix.

Note that the rows and the columns extend in directions orthogonal to each other. In this embodiment, the X direction represents “row” and the Y direction represents “column”. Note that the X direction may represent “column” and the Y direction may represent “row”.

In FIG. 1A, the memory cell 100 in the first row and the first column is referred to as a memory cell 100[1,1], the memory cell 100 in the second row and the first column is referred to as a memory cell 100[2,1], and the memory cell 100 in the m-th row and the first column is referred to as a memory cell 100[m,1]. The memory cell 100 in the first row and the second column is referred to as a memory cell 100[1,2], and the memory cell 100 in the first row and the n-th column is referred to as a memory cell 100[1,n]. The memory cell 100 in the m-th row and the n-th column is referred to as a memory cell 100[m,n].

In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 100 in the i-th row and the j-th column is referred to as a memory cell 100[i,j]. Note that in this embodiment and the like, “i+a” (a is a positive or negative integer) is not below 1 and does not exceed m. Similarly, “j+a” is not below 1 and does not exceed n.

The semiconductor device 10 includes m conductors 262 extending in the row direction, m conductors 242 extending in the row direction, and n conductors 246 extending in the column direction. In this embodiment and the like, the i-th conductor 262 provided in the i-th row is referred to as a conductor 262[i], and the i-th conductor 242 provided in the i-th row is referred to as a conductor 242[i]. Similarly, the j-th conductor 246 provided in the j-th column is referred to as a conductor 246[j].

The memory cell 100[i,j] is electrically connected to the conductor 262[i], the conductor 242[i], and the conductor 246[ ]. In other words, the conductor 262[i] is electrically connected to n memory cells (a memory cell 100[i,1] to a memory cell 100[i,n]), the conductor 242[i] is electrically connected to n memory cells (the memory cell 100[i,1] to the memory cell 100[i,n]), and the conductor 246[j] is electrically connected to m memory cells (a memory cell 100[1,j] to a memory cell 100[m,j]).

The conductor 262 described below refers to any one or more of a conductor 262[1] to a conductor 262[m], and the conductor 242 described below refers to any one or more of a conductor 242[1] to a conductor 242[m]. Similarly, the conductor 246 described below refers to any one or more of a conductor 246[1] to a conductor 246[n]. Similarly, the memory cell 100 described below refers to any one or more of the memory cell 100[1,1] to the memory cell 100[m,n].

The conductor 262, the conductor 242, and the conductor 246 function as wirings. In the case where the semiconductor device 10 is used as a storage device, the direction in which the conductor 262 extends and the direction in which the conductor 246 extends are preferably different, and are further preferably orthogonal to each other. Furthermore, the direction in which the conductor 242 extends and the direction in which the conductor 246 extends are preferably different, and are further preferably orthogonal to each other.

### [Memory Cell 100]

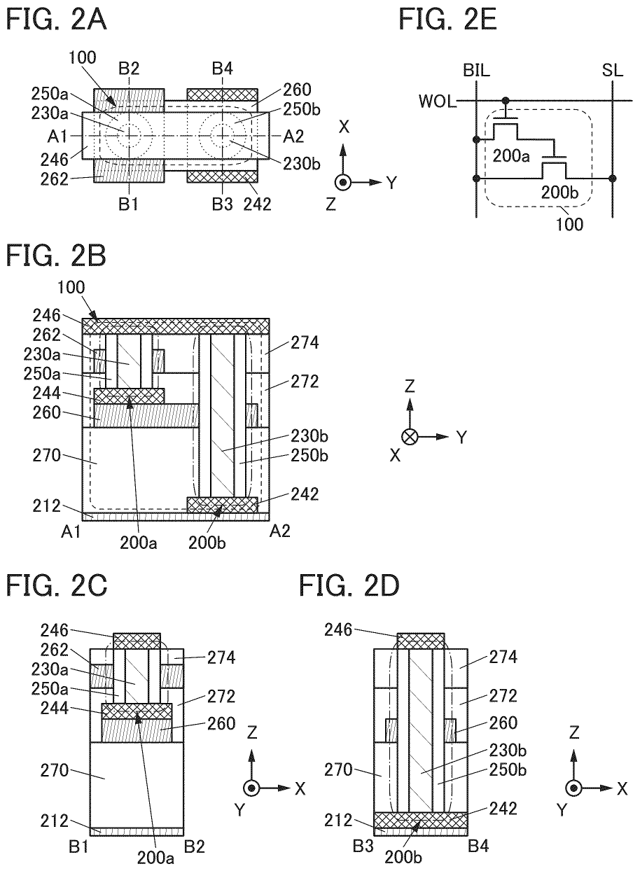

FIG. 2A to FIG. 2D are a top view and cross-sectional views illustrating a structure example of a memory cell included in the semiconductor device of one embodiment of the present invention. FIG. 2A is a top view of the memory cell 100. FIG. 2B is a cross-sectional view of the memory cell 100, and is a cross-sectional view of a portion indicated by the dashed-dotted line A1-A2 in FIG. 2A. FIG. 2C is a cross-sectional view of the memory cell 100, and is a cross-sectional view of a portion indicated by the dashed-dotted line B1-B2 in FIG. 2A. FIG. 2D is a cross-sectional view of the memory cell 100, and is a cross-sectional view of a portion indicated by the dashed-dotted line B3-B4 in FIG. 2A. Note that for clarity of the drawing, some components are omitted in the top view of FIG. 2A.

Since the memory cell 100[1,1] to the memory cell 100[m,n] have the same structure, they are denoted as the memory cell 100 in FIG. 2A and the like, and identification signs are not added thereto.

As illustrated in FIG. 2A to FIG. 2D, the semiconductor device of one embodiment of the present invention includes an insulator 212 over a substrate (not illustrated), the memory cell 100 over the insulator 212, an insulator 270 over the insulator 212, an insulator 272 over the insulator 270, and an insulator 274 over the insulator 272.

The memory cell 100 illustrated in FIG. 2A to FIG. 2D includes a transistor 200a and a transistor 200b. The transistor 200a and the transistor 200b are provided over the insulator 212.

The transistor 200a includes an oxide 230a, an insulator 250a, a conductor 244, the conductor 262 over the conductor 244, and the conductor 246 over the conductor 262. The insulator 272 includes a region positioned between the conductor 244 and the conductor 262, and the insulator 274 includes a region positioned between the conductor 262 and the conductor 246.

A first opening reaching the conductor 244 is provided in the insulator 272, the conductor 262, and the insulator 274. The first opening includes a region overlapping with the conductor 244 in the plan view. Note that it can be said that the first opening includes an opening included in the insulator 272, an opening included in the conductor 262, and an opening included in the insulator 274. It can be said that the conductor 262 has an opening overlapping with the conductor 244 in the plan view.

The insulator 250a and the oxide 230a are placed inside the first opening. The insulator 250a includes a region in contact with the side surface of the conductor 262 in the first opening. The insulator 250a includes a region in contact with the side surface of the insulator 272 in the first opening and a region in contact with the side surface of the insulator 274 in the first opening. The insulator 250a includes a region in contact with the side surface of the oxide 230a, a region in contact with the side surface of the conductor 262, a region in contact with at least part of the side surface of the insulator 272, and a region in contact with at least part of the side surface of the insulator 274. It can be said that the insulator 250a has a cylindrical shape provided with a hollow portion. The oxide 230a is provided to fill the first opening with the insulator 250a therebetween. The oxide 230a includes a region in contact with the side surface of the insulator 250a, a region in contact with at least part of the top surface of the conductor 244, and a region in contact with at least part of the bottom surface of the conductor 246. The oxide 230a includes a region facing the conductor 262 with the insulator 250a therebetween.

Although FIG. 2A illustrates a structure in which the top surface of the first opening provided with the oxide 230a and the insulator 250a has a circular shape, the present invention is not limited thereto. For example, the top surface of the first opening may have an oval shape, a polygonal shape, or a polygonal shape with rounded corners. The polygonal shape here means a triangle, a quadrangle, a pentagon, a hexagon, and the like.

The conductor 262 includes a region functioning as a gate electrode of the transistor 200a. The insulator 250a includes a region functioning as a gate insulator of the transistor 200a. Note that the gate insulator is also referred to as a gate insulating layer or a gate insulating film in some cases. The conductor 244 includes a region functioning as one of a source electrode and a drain electrode of the transistor 200a. The conductor 246 includes a region functioning as the other of the source electrode and the drain electrode of the transistor 200a. The region of the oxide 230a that faces the conductor 262 with the insulator 250a therebetween functions as a channel formation region of the transistor 200a.

The transistor 200b includes an oxide 230b, an insulator 250b, the conductor 242, a conductor 260 over the conductor 242, and the conductor 246 over the conductor 260. The insulator 270 includes a region positioned between the conductor 242 and the conductor 260, and the insulator 272 and the insulator 274 each include a region positioned between the conductor 260 and the conductor 246.

A second opening reaching the conductor 242 is provided in the insulator 270, the conductor 260, the insulator 272, and the insulator 274. The second opening includes a region overlapping with the conductor 242 in the plan view. Note that it can be said that the second opening includes an opening included in the insulator 270, an opening included in the conductor 260, an opening included in the insulator 272, and an opening included in the insulator 274. It can be said that the conductor 260 has an opening overlapping with the conductor 242 in the plan view.

The insulator 250b and the oxide 230b are placed inside the second opening. The insulator 250b includes a region in contact with the side surface of the conductor 260 in the second opening. The insulator 250b includes a region in contact with the side surface of the insulator 270 in the second opening, a region in contact with the side surface of the insulator 272 in the second opening, and a region in contact with the side surface of the insulator 274 in the second opening. The insulator 250b includes a region in contact with the side surface of the oxide 230b, a region in contact with the side surface of the conductor 260, a region in contact with at least part of the side surface of the insulator 270, a region in contact with at least part of the side surface of the insulator 272, and a region in contact with at least part of the side surface of the insulator 274. It can be said that the insulator 250b has a cylindrical shape provided with a hollow portion. The oxide 230b is provided to fill the second opening with the insulator 250b therebetween. The oxide 230b includes a region in contact with the side surface of the insulator 250b, a region in contact with at least part of the top surface of the conductor 242, and a region in contact with at least part of the bottom surface of the conductor 246. The oxide 230b includes a region facing the conductor 260 with the insulator 250b therebetween.

Although FIG. 2A illustrates a structure in which the top surface of the second opening provided with the oxide 230b and the insulator 250b has a circular shape, the present invention is not limited thereto. For example, the top surface of the opening may have an oval shape, a polygonal shape, or a polygonal shape with rounded corners.

The conductor 260 includes a region functioning as a gate electrode of the transistor 200b. The insulator 250b includes a region functioning as a gate insulator of the transistor 200b. The conductor 242 includes a region functioning as one of a source electrode and a drain electrode of the transistor 200b. The conductor 246 includes a region functioning as the other of the source electrode and the drain electrode of the transistor 200b. The region of the oxide 230b that faces the conductor 260 with the insulator 250b therebetween functions as a channel formation region of the transistor 200b.

In the following description of matters common to components distinguished from each other using letters of the alphabet, reference numerals without the letters of the alphabet are sometimes used. For example, in the case where matters common to the transistor 200a and the transistor 200b are described, the term “transistor 200” is sometimes used. In the case where matters common to the oxide 230a and the oxide 230b are described, the term “oxide 230” is sometimes used. In the case where matters common to the insulator 250a and the insulator 250b are described, the term “insulator 250” is sometimes used.

The transistor 200 is what is called a vertical transistor in which one of a source electrode and a drain electrode is positioned below a channel formation region and the other of the source electrode and the drain electrode is positioned above the channel formation region, whereby current flows in the vertical direction. The transistor 200 has a structure in which the gate electrode surrounds the channel formation region. Thus, the transistor 200 can be referred to as a transistor having a GAA (Gate-All-Around) structure or a transistor having a vertical GAA structure.

Note that the channel length of the transistor 200 refers to the length of a region where a semiconductor (or a portion where current flows in a semiconductor when the transistor is on) and the gate electrode face each other, or the distance between the source (the source region or the source electrode) and the drain (the drain region or the drain electrode) in the channel formation region in the cross-sectional view.

The channel length of the transistor 200a corresponds to the length of the oxide 230a in the Z direction, and the length of the oxide 230a in the Z direction is equal to or substantially equal to the depth (the length in the Z direction) of the first opening provided with the oxide 230a. Thus, the channel length of the transistor 200a can be adjusted by the depth (the length in the Z direction) of the first opening. Note that in the case where the conductor 244 does not have a depressed portion in a region overlapping with the first opening, the channel length of the transistor 200a can sometimes be regarded as the shortest distance from the top surface of the conductor 244 to the bottom surface of the conductor 246 in the cross-sectional view. In other words, the depth (the length in the Z direction) of the first opening is equal to or substantially equal to the sum of the thickness of a region of the insulator 272 that overlaps with the conductor 244 and the thickness of the insulator 274. That is, the channel length of the transistor 200a can be adjusted by the thickness of the insulator 272, the thickness of the conductor 262, and the thickness of the insulator 274. For example, when the thicknesses of the insulator 272 and the insulator 274 are made small, the transistor 200a having a short channel length can be manufactured.

The channel length of the transistor 200b corresponds to the length of the oxide 230b in the Z direction, and the length of the oxide 230b in the Z direction is equal to or substantially equal to the depth (the length in the Z direction) of the second opening provided with the oxide 230b. Thus, the channel length of the transistor 200b can be adjusted by the depth (the length in the Z direction) of the second opening. Note that in the case where the conductor 242 does not have a depressed portion in a region overlapping with the second opening, the channel length of the transistor 200b can sometimes be regarded as the shortest distance from the top surface of the conductor 242 to the bottom surface of the conductor 246 in the cross-sectional view. In other words, the depth (the length in the Z direction) of the second opening is equal to or substantially equal to the sum of the thickness of a region of the insulator 270 that overlaps with the conductor 242, the thickness of the insulator 272, and the thickness of the insulator 274. That is, the channel length of the transistor 200b can be adjusted by the thickness of the insulator 270, the thickness of the insulator 272, and the thickness of the insulator 274. For example, when the thicknesses of the insulator 270, the insulator 272, and the insulator 274 are made small, the transistor 200b having a short channel length can be manufactured.

Note that since the OS transistor has an extremely low off-state current, the transistor 200 even with a short channel length can have a low off-state current.

Meanwhile, in the case where a transistor operates in a saturation region, the channel length of the transistor is sometimes lengthened so that its electrical characteristics in the saturation region can be improved. Since the transistor 200 is a vertical transistor, the area occupied by the transistor 200 in the plan view does not depend on the above-described thickness. Thus, the transistor 200 may have a long channel length.

In view of the above, the channel length of the transistor 200 is greater than or equal to 10 nm and less than or equal to 200 nm, preferably greater than or equal to 20 nm and less than or equal to 150 nm, further preferably greater than or equal to 30 nm and less than or equal to 100 nm.

Note that the channel width of the transistor 200 refers to the length of a region where a semiconductor (or a portion where current flows in a semiconductor when the transistor is on) and the gate electrode face each other, or the length of the channel formation region in a direction perpendicular to the channel length direction (Z direction) in the channel formation region in the plan view. That is, the channel width of the transistor 200 corresponds to the outer perimeter of the oxide 230 in the plan view. Note that in one transistor, channel widths in all regions do not necessarily have the same value. In other words, the channel width of one transistor is not fixed to one value in some cases. Examples of such a case include a case where the side surface of the oxide 230 has a tapered shape in the cross-sectional view of the transistor as described later. Thus, in this specification and the like, the channel width is any one of the values, the maximum value, the minimum value, or the average value in a channel formation region.

Note that the channel length and the channel width can be determined by analyzing a cross-sectional TEM image, for example.

In the case where a memory cell is formed using the first transistor and the second transistor, one of the source electrode and the drain electrode of the first transistor needs to be connected to the gate electrode of the second transistor. In the case of providing an electrode (also referred to as a connection electrode) for connecting one of the source electrode and the drain electrode of the first transistor and the gate electrode of the second transistor, provision of a region where the connection electrode is placed might increase the area occupied by the memory cell and decrease the integration degree of the memory cell.

In one embodiment of the present invention, the conductor 244 includes a region in contact with the conductor 260. For example, the conductor 244 includes a region in contact with the top surface of the conductor 260. When the conductor 244 includes a region in contact with the conductor 260, one of the source electrode and the drain electrode of the transistor 200a is directly connected to the gate electrode of the transistor 200b. Accordingly, it is not necessary to provide an electrode for connecting one of the source electrode and the drain electrode of the transistor 200a and the gate electrode of the transistor 200b; thus, the memory cell can be formed without reducing transistor density. Therefore, the memory cell can have a high degree of integration and large memory capacity. Moreover, the number of steps in the manufacturing process of the semiconductor device can be reduced.

As illustrated in FIG. 2B, the length of the oxide 230b in the Z direction is longer than the length of the oxide 230a in the Z direction by the thickness of the region of the insulator 270 that overlaps with the conductor 242, the thickness of the conductor 260, and the thickness of the conductor 244. When the channel length of the transistor 200b is lengthened, variation in the threshold voltage (Vth) of the transistor 200b functioning as a read transistor is reduced. Therefore, a memory cell and a semiconductor device which have high reading accuracy can be provided. Moreover, when the channel length of the transistor 200a functioning as a write transistor is shortened, a memory cell and a semiconductor device which allow high-speed writing can be provided.

As illustrated in FIG. 2A, the conductor 262 and the conductor 242 are provided to extend in the X direction. That is, the direction in which the conductor 262 extends is parallel to the direction in which the conductor 242 extends. The conductor 246 is provided to extend in the Y direction. That is, the conductor 246 extends in the direction orthogonal to the direction in which the conductor 262 extends. The conductor 246 extends in the direction orthogonal to the direction in which the conductor 242 extends.

In the transistor 200, a metal oxide functioning as a semiconductor (hereinafter also referred to as an oxide semiconductor) is preferably used for the oxide 230 including the channel formation region.

The oxide 230 preferably includes a metal oxide (oxide semiconductor). Examples of the metal oxide that can be used for the oxide 230 include an indium oxide, a gallium oxide, and a zinc oxide. The metal oxide preferably contains at least indium (In) or zinc (Zn). The metal oxide preferably contains two or three selected from indium, the element M, and zinc. The element M is a metal element or metalloid element that has a high bonding energy with oxygen, such as a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For the oxide 230, for example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (In—Ga—Sn oxide), a gallium zinc oxide (Ga—Zn oxide, also referred to as GZO), an aluminum zinc oxide (Al—Zn oxide), an indium aluminum zinc oxide (In—Al—Zn oxide, also referred to as IAZO), an indium tin zinc oxide (In—Sn—Zn oxide), an indium titanium zinc oxide (In—Ti—Zn oxide), an indium gallium zinc oxide (In—Ga—Zn oxide, also referred to as IGZO), an indium gallium tin zinc oxide (In—Ga—Sn—Zn oxide, also referred to as IGZTO), and an indium gallium aluminum zinc oxide (In—Ga—Al—Zn oxide, also referred to as IGAZO or IAGZO) can be used. Alternatively, an indium tin oxide containing silicon, an gallium tin oxide (Ga—Sn oxide), an aluminum tin oxide (Al—Sn oxide), or the like can be used.

By increasing the proportion of the number of indium atoms in the total number of atoms of all the metal elements contained in the metal oxide, the field-effect mobility of the transistor can be increased.

Instead of indium or in addition to indium, the metal oxide may contain one or more kinds of metal elements with large period numbers in the periodic table. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include Period 5 metal elements and Period 6 metal elements. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. When a nonmetallic element is contained in the metal oxide, the field-effect mobility of the transistor can be increased in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in the electrical characteristics of the transistor is reduced and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in the electrical characteristics of the transistor is reduced and the transistor can have high reliability.

Specifically, as the oxide 230, a metal oxide having a composition where In:M:Zn=1:1:1 [atomic ratio] or a neighborhood thereof, a metal oxide having a composition where In:M:Zn=1:1:1.2 [atomic ratio] or a neighborhood thereof, a metal oxide having a composition where In:M:Zn=1:1:2 [atomic ratio] or a neighborhood thereof, or a metal oxide having a composition where In:M:Zn=4:2:3 [atomic ratio] or a neighborhood thereof can be used. Note that a composition in the neighborhood includes the range of ±30% of an intended atomic ratio. Gallium is preferably used as the element M.

As described above, electrical characteristics and reliability of a transistor vary depending on the composition of the metal oxide used for the oxide 230. Therefore, by determining the composition of the metal oxide in accordance with the electrical characteristics and reliability required for the transistor, the semiconductor device can have both favorable electrical characteristics and high reliability.

When the substrate floating effect is caused by use of silicon for the channel formation region of a transistor with a short channel length, the electrical characteristics of the transistor are unstable. By contrast, metal oxides such as IGZO, IAZO, and IAGZO have a high hole effective mass. Accordingly, when any of the above metal oxides is used for a channel formation region, hole accumulation in the channel formation region can be inhibited, so that a transistor suffering from little impact or substantially no impact of the substrate floating effect can be fabricated. That is, a transistor even with a short channel length can have stable electrical characteristics by including the above metal oxide in a channel formation region. Thus, a transistor having favorable electrical characteristics and a semiconductor device including the transistor can be provided. Moreover, a transistor with a small variation in electrical characteristics and a semiconductor device including the transistor can be provided.

If impurities and oxygen vacancies exist in a channel formation region in an oxide semiconductor, electrical characteristics of the transistor including the oxide semiconductor easily vary and the reliability thereof might worsen. Hydrogen in the vicinity of an oxygen vacancy may form a defect that is the oxygen vacancy into which hydrogen enters (hereinafter sometimes referred to as V_{O}H), which may generate an electron serving as a carrier. Accordingly, when the channel formation region in the oxide semiconductor includes oxygen vacancies, the transistor tends to have normally-on characteristics (characteristics with which a channel exists and a current flows through the transistor even when no voltage is applied to the gate electrode). Thus, impurities, oxygen vacancies, and V_{O}H are preferably reduced as much as possible in the channel formation region in the oxide semiconductor.

As a countermeasure against the above, an insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H.

In order to obtain stable electrical characteristics of the transistor, reducing the concentration of impurities in the oxide 230 is effective. In order to reduce the impurity concentration in the oxide 230, the impurity concentration in a film that is adjacent to the oxide 230 is also preferably reduced.

An oxide semiconductor having crystallinity is preferably used as the oxide 230. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the oxide 230, the CAAC-OS or the nc-OS is preferably used, and the CAAC-OS is particularly preferably used.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Thus, the metal oxide including a CAAC-OS is resistant to heat and has high reliability.

When an oxide having crystallinity, such as a CAAC-OS, is used as the oxide 230, oxygen extraction from the oxide 230 by the conductor 242, the conductor 244, the conductor 246, the conductor 260, and the conductor 262 can be inhibited. This can suppress oxygen extraction from the oxide 230 even when heat treatment is performed; thus, the transistor is stable with respect to high temperatures in a manufacturing process (what is called thermal budget). Furthermore, it is possible to inhibit a reduction in the conductivity of the conductor 242, the conductor 244, the conductor 246, the conductor 260, and the conductor 262.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal (also referred as nanocrystal). Furthermore, there is no regularity of crystal orientation between different nanocrystal parts in the nc-OS film; thus, the orientation of the whole film is not observed. That is, in the case where the nc-OS is used as the oxide 230, the oxide 230 has uniform film characteristics regardless of the direction of carriers flowing in the oxide 230; thus, the transistor has stable electrical characteristics.

Note that an oxide semiconductor has various structures with different properties. The oxide 230 may include two or more kinds of the CAAC-OS, the nc-OS, an amorphous-like oxide semiconductor (a-like OS), an amorphous oxide semiconductor, a polycrystalline oxide semiconductor, and a CAC-OS (cloud-aligned composite oxide semiconductor).

Note that when the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS. For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

In some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter equivalent to or less than the diameter of a nanocrystal (e.g., greater than or equal to 1 nm and less than or equal to 30 nm).

The oxide 230 can be rephrased as a semiconductor layer including the channel formation region of the transistor 200. Note that a material that can be used for the semiconductor layer is not limited to a metal oxide functioning as a semiconductor (an oxide semiconductor). For example, a semiconductor such as single crystal silicon, polycrystalline silicon, or amorphous silicon may be used for the semiconductor layer, and low-temperature polysilicon (LTPS) may be used, for example.

Alternatively, for the semiconductor layer, transition metal chalcogenide functioning as a semiconductor may be used; for example, molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), or zirconium selenide (typically ZrSe₂) may be used.

The insulator 250 may have either a single-layer structure or a stacked-layer structure.

As the insulator 250, for example, silicon oxide, silicon oxynitride, silicon oxide to which fluorine is added, silicon oxide to which carbon is added, silicon oxide to which carbon and nitrogen are added, porous silicon oxide, or the like can be used. In particular, silicon oxide and silicon oxynitride, which are thermally stable, are preferable. The insulator 250 in this case contains at least oxygen and silicon.

The concentration of impurities such as water and hydrogen in the insulator 250 is preferably reduced.

The insulator 250a and the insulator 250b are formed in the same step, which will be described later in detail. Thus, the insulator 250a and the insulator 250b contain the same insulating material. In addition, the thickness of the insulator 250a is equal to the thickness of the insulator 250b.

Note that an insulator having a barrier property against oxygen may be provided between the insulator 250 and the oxide 230. The insulator is provided in contact with the side surface of the insulator 250 and the side surface of the oxide 230. When the insulator has a barrier property against oxygen, oxygen contained in the insulator 250 can be supplied to the channel formation region, while oxygen contained in the insulator 250 can be inhibited from being excessively supplied to the channel formation region. Thus, it is possible to inhibit release of oxygen from the oxide 230 when heat treatment or the like is performed and inhibit formation of oxygen vacancies in the oxide 230. Thus, the transistor 200 can have favorable electrical characteristics and higher reliability.

An insulator containing an oxide of one or both of aluminum and hafnium is preferably used as the insulator having a barrier property against oxygen. As the insulator, aluminum oxide, hafnium oxide, an oxide containing aluminum and hafnium (hafnium aluminate), an oxide containing hafnium and silicon (hafnium silicate), or the like can be used. As the above insulator, aluminum oxide is further preferably used. In this case, the above insulator contains at least oxygen and aluminum. Note that oxygen is less likely to pass through the above insulator than the insulator 250, for example. For the above insulator, a material through which oxygen is less likely to pass than the insulator 250 is used, for example. For the above insulator, magnesium oxide, gallium oxide, gallium zinc oxide, or indium gallium zinc oxide may be used, for example.

To form the oxide 230 and the insulator 250 in the opening provided in the insulator 272, the insulator 274, and the like, the oxide 230 and the insulator 250 are preferably formed using an atomic layer deposition (ALD) method. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because film formation at a lower temperature is possible.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Thus, the oxide 230 and the insulator 250 can be formed on the side surface of the opening portion provided in the insulator 272, the insulator 274, and the like with good coverage.

Note that some of precursors used in an ALD method contain carbon, for example. Thus, in some cases, a film provided by an ALD method contains impurities such as carbon in a larger amount than a film provided by another film formation method. Note that impurities can be quantified by secondary ion mass spectrometry (SIMS), X-ray photoelectron spectroscopy (XPS), or auger electron spectroscopy (AES).

The conductor 242 is provided over the insulator 212. The conductor 244 is provided over the conductor 260. The conductor 246 is provided over the insulator 274.

A conductive material that is not easily oxidized or a conductive material having a function of inhibiting oxygen diffusion is preferably used for each of the conductor 242, the conductor 244, and the conductor 246. Examples of the conductive material include a conductive material containing nitrogen and a conductive material containing oxygen. With use of the conductive material, a reduction in the conductivity of the conductor 242, the conductor 244, and the conductor 246 can be inhibited. In the case where a conductive material containing metal and nitrogen is used for each of the conductor 242, the conductor 244, and the conductor 246, each of the conductor 242, the conductor 244, and the conductor 246 contains at least metal and nitrogen.

As each of the conductor 242, the conductor 244, and the conductor 246, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

FIG. 2B to FIG. 2D illustrate a structure in which each of the conductor 242, the conductor 244, and the conductor 246 is a single layer. Note that one or two or more of the conductor 242, the conductor 244, and the conductor 246 may have a stacked-layer structure of two or more layers.

For example, each of the conductor 242 and the conductor 246 may have a two-layer structure of a first conductor and a second conductor. In that case, a conductive material that is not easily oxidized or a conductive material having a function of inhibiting diffusion of oxygen is preferably used for the first conductor, which is in contact with the oxide 230, of each of the conductor 242 and the conductor 246. Thus, a decrease in conductivity of the conductor 242 and the conductor 246 can be inhibited.

The conductor 242 and the conductor 246 also function as wirings and thus are each preferably formed using a conductor having high conductivity. Thus, the second conductor, which is positioned on the side not in contact with the oxide 230, of each of the conductor 242 and the conductor 246 preferably has higher conductivity than the first conductor of each of the conductor 242 and the conductor 246. For example, a conductive material containing tungsten, copper, or aluminum as its main component can be used for the second conductor of each of the conductor 242 and the conductor 246. In addition, the thickness of the second conductor of each of the conductor 242 and the conductor 246 is preferably larger than the thickness of the first conductor of each of the conductor 242 and the conductor 246.

For example, tantalum nitride or titanium nitride can be used for the first conductor of each of the conductor 242 and the conductor 246, and tungsten can be used for the second conductor of each of the conductor 242 and the conductor 246. Note that in the case where the conductor 244 has a stacked-layer structure, the structure may be similar to the stacked-layer structures of the conductor 242 and the conductor 246.

FIG. 2B and FIG. 2C illustrate a structure in which the conductor 244 does not have a depressed portion in the region overlapping with the first opening provided with the oxide 230a and the insulator 250a. Note that the present invention is not limited thereto. The conductor 244 may have a depressed portion in the region overlapping with the first opening. In other words, the top surface of the conductor 244 in the region overlapping with the first opening may be partly removed.

Similarly, FIG. 2B and FIG. 2D illustrate a structure in which the conductor 242 does not have a depressed portion in the region overlapping with the second opening provided with the oxide 230b and the insulator 250b. Note that the present invention is not limited thereto. The conductor 242 may have a depressed portion in the region overlapping with the second opening. In other words, the top surface of the conductor 242 in the region overlapping with the second opening may be partly removed.

The conductor 260 is provided over the insulator 270. The conductor 262 is provided over the insulator 272.

The conductor 260 and the conductor 262 are each preferably formed using a conductor having high conductivity. For example, a conductive material containing tungsten, copper, or aluminum as its main component can be used for each of the conductor 260 and the conductor 262.

Although FIG. 2B to FIG. 2D illustrate a structure in which each of the conductor 260 and the conductor 262 is a single layer, the present invention is not limited thereto. One or both of the conductor 260 and the conductor 262 may have a stacked-layer structure of two or more layers.

The insulator 212 preferably functions as a barrier insulating film that inhibits diffusion of impurities such as water and hydrogen into the transistor from the substrate side. Accordingly, the insulator 212 preferably includes an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the above impurities are less likely to pass). Alternatively, the insulator 212 preferably includes an insulating material having a function of inhibiting diffusion of oxygen (e.g., at least one of an oxygen atom, an oxygen molecule, and the like) (an insulating material through which the oxygen is less likely to pass).

The insulator 212 preferably includes an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a high hydrogen barrier property, is preferably used for the insulator 212. For example, the insulator 212 preferably contains aluminum oxide, magnesium oxide, or the like, which has a function of trapping and fixing hydrogen well. In this case, impurities such as water and hydrogen can be inhibited from diffusing to the transistor from the substrate side through the insulator 212. It is also possible to inhibit diffusion of oxygen contained in the insulator 270 and the like toward the substrate.

Note that in this specification and the like, a barrier insulating film refers to an insulating film having a barrier property. A barrier property in this specification and the like means a function of inhibiting diffusion of a targeted substance (also referred to as having low permeability). In addition, a barrier property in this specification and the like means a function of capturing and fixing (also referred to as gettering) a targeted substance.

The insulator 270 is provided over the insulator 212 and the conductor 242. The insulator 272 is provided over the insulator 270, the conductor 260, and the conductor 244. The insulator 274 is provided over the insulator 272 and the conductor 262.

An insulator containing excess oxygen is preferably used as the insulator 270, the insulator 272, and the insulator 274 that have the opening provided with the insulator 250 and the oxide 230. For each of the insulator 270, the insulator 272, and the insulator 274, it is preferable to use an oxide containing silicon, such as silicon oxide, silicon oxynitride, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. A material such as silicon oxide, silicon oxynitride, or porous silicon oxide is preferable because a region containing excess oxygen can be easily formed. When an insulator containing excess oxygen is provided in the vicinity of the oxide 230 and heat treatment is performed, oxygen can be supplied from the insulator to the oxide 230 and oxygen vacancies and V_{O}H can be reduced.

The concentration of impurities such as water and hydrogen in each of the insulator 270, the insulator 272, and the insulator 274 is preferably reduced. For example, the insulator 270, the insulator 272, and the insulator 274 each preferably contain an oxide containing silicon, such as silicon oxide or silicon oxynitride.

The insulator 270, the insulator 272, and the insulator 274 function as interlayer films. The permittivity of each of the insulator 270, the insulator 272, and the insulator 274 is preferably lower than that of the insulator 212. When a material with a low permittivity is used for an interlayer film, parasitic capacitance generated between wirings can be reduced.

For example, each of the insulator 270, the insulator 272, and the insulator 274 preferably contains one or more of silicon oxide, silicon oxynitride, silicon oxide to which fluorine is added, silicon oxide to which carbon is added, silicon oxide to which carbon and nitrogen are added, and porous silicon oxide.

Each of the top surfaces of the insulator 270, the insulator 272, and the insulator 274 may be planarized.

The semiconductor device including the memory cell 100 can be used as a storage device. FIG. 2E illustrates a circuit diagram of the semiconductor device including the memory cell 100, which is used as a storage device. The memory cell 100 includes the transistor 200a and the transistor 200b.

As illustrated in FIG. 2E, the gate of the transistor 200a is electrically connected to a wiring WOL, one of the source and the drain of the transistor 200a is electrically connected to the gate of the transistor 200b, and the other of the source and the drain of the transistor 200b is electrically connected to a wiring BIL. One of the source and the drain of the transistor 200b is electrically connected to a wiring SL, and the other of the source and the drain of the transistor 200b is electrically connected to the wiring BIL.

The wiring WOL functions as a word line, the wiring BIL functions as a bit line, and the wiring SL functions as a selection line.

The wiring WOL corresponds to the conductor 262, the wiring BIL corresponds to the conductor 246, and the wiring SL corresponds to the conductor 242. That is, the conductor 262 includes a region functioning as a word line, the conductor 246 includes a region functioning as a bit line, and the conductor 242 includes a region functioning as a selection line.

Note that the structure of the memory cell and the storage device including the memory cell will be described in Embodiment 2.

As illustrated in FIG. 2B to FIG. 2D, the side surface of the opening of the conductor 260 is in contact with the insulator 250b. Here, an insulator is formed between the conductor 260 and the insulator 250b in some cases. The side surface of the opening of the conductor 262 is in contact with the insulator 250a. Here, an insulator is formed between the conductor 262 and the insulator 250a in some cases.

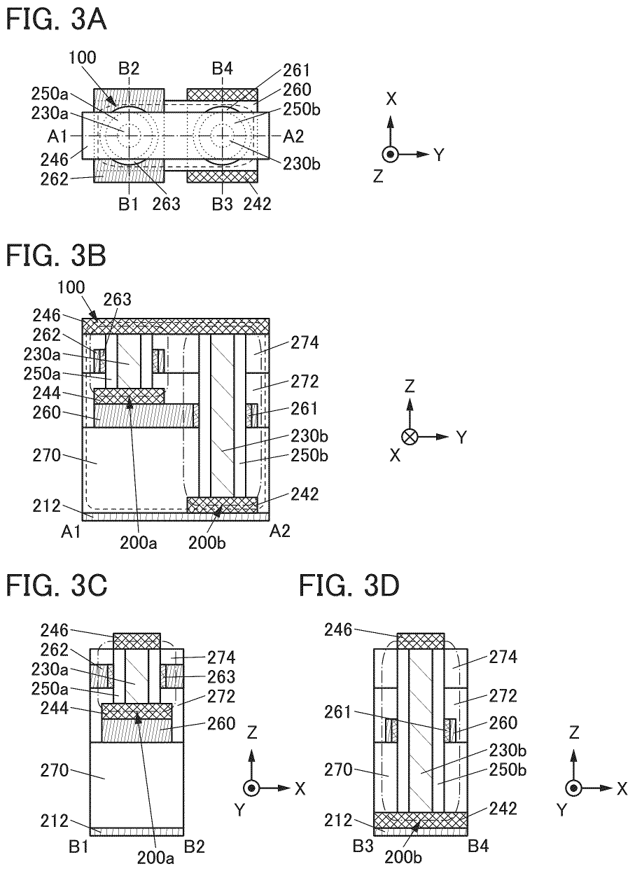

FIG. 3A is atop view of the memory cell 100. FIG. 3B is a cross-sectional view of the memory cell 100, and is a cross-sectional view of a portion indicated by the dashed-dotted line A1-A2 in FIG. 3A. FIG. 3C is a cross-sectional view of the memory cell 100, and is a cross-sectional view of a portion indicated by the dashed-dotted line B1-B2 in FIG. 3A. FIG. 3D is a cross-sectional view of the memory cell 100, and is a cross-sectional view of a portion indicated by the dashed-dotted line B3-B4 in FIG. 3A. Note that for clarity of the drawing, some components are omitted in the top view of FIG. 3A.

In the memory cell 100 illustrated in FIG. 3A to FIG. 3D, an insulator 261 is provided between the conductor 260 and the insulator 250b, and an insulator 263 is provided between the conductor 262 and the insulator 250a.

The insulator 261 functions as the gate insulator of the transistor 200b. Thus, it is preferable to set the thickness of the insulator 250b, the size of the second opening provided with the insulator 250b, or the like as appropriate in accordance with characteristics required for the transistor 200b, while considering the size of the insulator 261 in the A1-A2 direction. The insulator 263 functions as the gate insulator of the transistor 200a. Thus, it is preferable to set the thickness of the insulator 250a, the size of the first opening provided with the insulator 250a, or the like as appropriate in accordance with characteristics required for the transistor 200a, while considering the size of the insulator 263 in the A1-A2 direction.

The insulator 261 contains an element contained in the conductor 260 and oxygen. Similarly, the insulator 263 contains an element contained in the conductor 262 and oxygen. For example, in the case where a material containing a metal element is used for each of the conductor 260 and the conductor 262, the insulator 261 and the insulator 263 each contain the metal element and oxygen. For another example, in the case where a conductive material containing a metal element and nitrogen is used for each of the conductor 260 and the conductor 262, the insulator 261 and the insulator 263 each contain the metal element, oxygen, and nitrogen.

Although FIG. 2B to FIG. 2D illustrate a structure in which a sidewall of the opening portion provided with the oxide 230 and the insulator 250 is perpendicular to the substrate surface (not illustrated), the present invention is not limited thereto. The sidewall of the opening portion may have a tapered shape with respect to the substrate surface. In this specification and the like, a sidewall of an opening portion refers to the side surface of an opening in a structure where the opening is provided. Thus, “sidewall of opening portion” described in this specification and the like can be rephrased as the side surface of an opening in a structure where the opening is provided. For example, the sidewall of the first opening portion can be rephrased as the side surface of at least one of the insulator 272, the conductor 262, and the insulator 274 in the first opening. For example, the sidewall of the second opening portion can be rephrased as the side surface of at least one of the insulator 270, the conductor 260, the insulator 272, and the insulator 274 in the second opening. In addition, “sidewall of opening portion” described in this specification and the like is sometimes referred to as “sidewall of opening”.

In this specification and the like, a tapered shape refers to a shape such that at least part of the side surface of a structure is inclined with respect to the substrate surface or the formation surface. For example, a tapered shape refers to a shape including a region where the angle formed by the inclined side surface and the substrate surface or the formation surface (such an angle is also referred to as a taper angle) is less than 90°. Note that the side surface of the structure and the substrate surface are not necessarily completely flat and may be substantially flat with a slight curvature or substantially flat with slight unevenness.

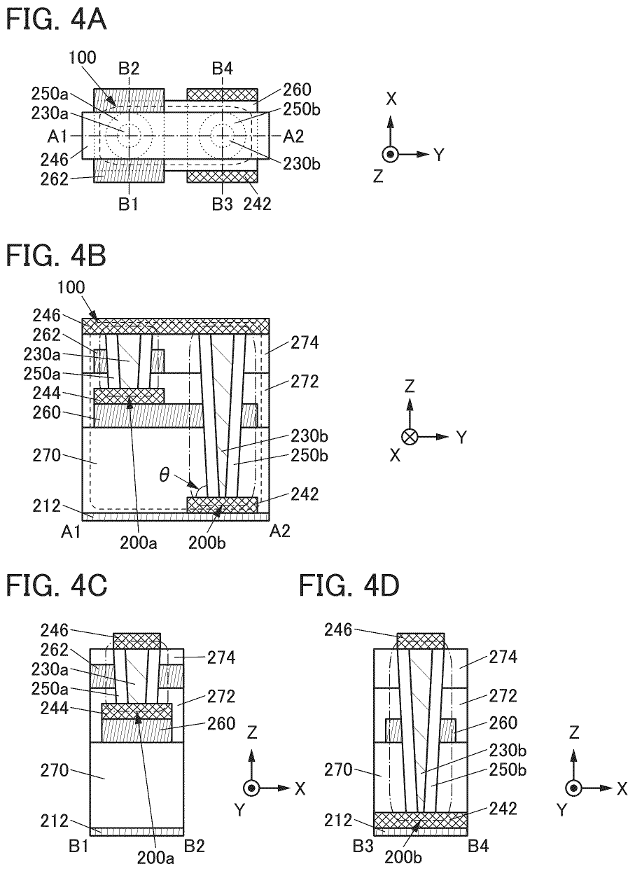

FIG. 4A is atop view of the memory cell 100. FIG. 4B is a cross-sectional view of the memory cell 100, and is a cross-sectional view of a portion indicated by the dashed-dotted line A1-A2 in FIG. 4A. FIG. 4C is a cross-sectional view of the memory cell 100, and is a cross-sectional view of a portion indicated by the dashed-dotted line B1-B2 in FIG. 4A. FIG. 4D is a cross-sectional view of the memory cell 100, and is a cross-sectional view of a portion indicated by the dashed-dotted line B3-B4 in FIG. 4A. Note that for clarity of the drawing, some components are omitted in the top view of FIG. 4A.

As illustrated in FIG. 4B and FIG. 4D, the sidewall of the second opening portion provided in the insulator 270, the conductor 260, the insulator 272, and the insulator 274 may have a tapered shape with a taper angle θ in the cross-sectional view. Here, the taper angle θ is an angle formed by the sidewall of the second opening portion and the substrate surface. Note that one of two sides extending from the vertex of the taper angle θ is not limited to the substrate surface and may be the top surface of the conductor 242. That is, the taper angle θ may be an angle formed by the sidewall of the second opening portion and the top surface of the conductor 242.

When the sidewall of the second opening portion has a tapered shape, the coverage with the insulator 250b provided inside the second opening is improved, so that a defect such as a void can be reduced. Furthermore, the coverage with the oxide 230b provided over the insulator 250b is improved, so that a defect such as a void can be reduced.

In the case of employing the above structure, the sidewall of the first opening portion provided in the insulator 272, the conductor 262, and the insulator 274 has a tapered shape in the cross-sectional view. The angle formed by the sidewall of the first opening portion and the substrate surface is equal to or substantially equal to the taper angle θ. Note that depending on the combination of a material used for the insulator 270 and a material used for the insulator 272, for example, the angle formed by the sidewall of the first opening portion and the substrate surface is not equal to the taper angle θ in some cases.

When the sidewall of the first opening portion has a tapered shape, the coverage with the insulator 250a provided inside the first opening is improved, so that a defect such as a void can be reduced. Furthermore, the coverage with the oxide 230a provided over the insulator 250a is improved, so that a defect such as a void can be reduced.

As the taper angle θ is closer to 90°, the area occupied by the transistor 200 can be reduced. For example, the taper angle θ is preferably greater than or equal to 80°, greater than or equal to 85°, or greater than or equal to 87° and less than 90°.

### [Modification Example of Memory Cell 100]

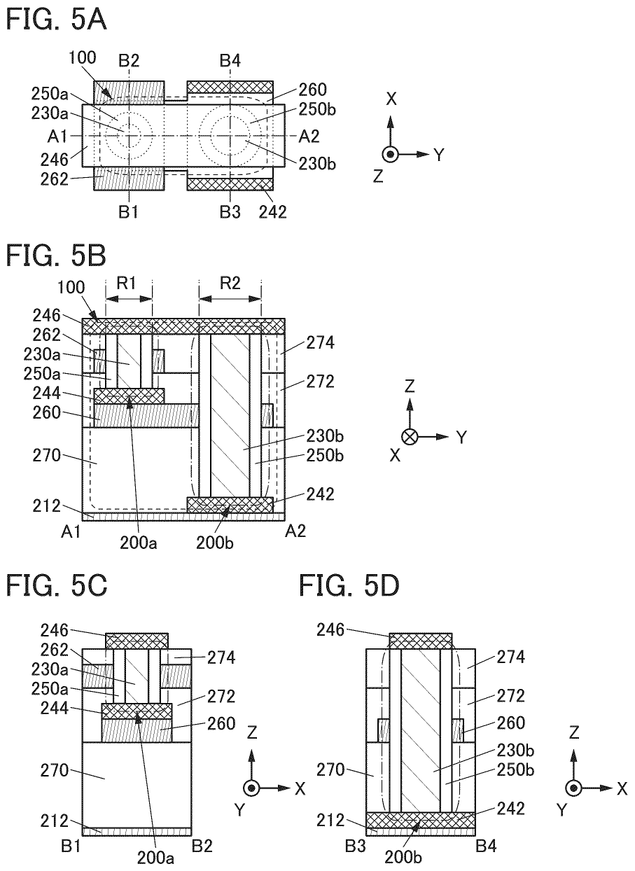

Modification examples of the memory cell 100 illustrated in FIG. 2A to FIG. 2D are described below with reference to FIG. 5A to FIG. 8A.

A modification example of the memory cell 100 illustrated in FIG. 2A to FIG. 2D is illustrated in FIG. 5A to FIG. 5D. FIG. 5A is a top view of the memory cell 100. FIG. 5B is a cross-sectional view of the memory cell 100, and is a cross-sectional view of a portion indicated by the dashed-dotted line A1-A2 in FIG. 5A. FIG. 5C is a cross-sectional view of the memory cell 100, and is a cross-sectional view of a portion indicated by the dashed-dotted line B1-B2 in FIG. 5A. FIG. 5D is a cross-sectional view of the memory cell 100, and is a cross-sectional view of a portion indicated by the dashed-dotted line B3-B4 in FIG. 5A. Note that for clarity of the drawing, some components are omitted in the top view of FIG. 5A.

The memory cell 100 illustrated in FIG. 5A to FIG. 5D is different from the memory cell 100 illustrated in FIG. 2A to FIG. 2B in that the size of the first opening provided with the oxide 230a and the insulator 250a is different from the size of the second opening provided with the oxide 230b and the insulator 250b.

As illustrated in FIG. 5B, a width R1 is the width of the first opening provided with the oxide 230a and the insulator 250a (the first opening provided in the insulator 272, the conductor 262, and the insulator 274), and a width R2 is the width of the second opening provided with the oxide 230b and the insulator 250b (the second opening provided in the insulator 270, the conductor 260, the insulator 272, and the insulator 274). Note that the width R1 can be regarded as the diameter of the first opening in the plan view. The width R2 can be regarded as the diameter of the second opening in the plan view.

The width R2 is preferably larger than the width R1. As described later in detail, the insulator 250a and the insulator 250b are formed using the same insulating film and thus have the same thickness. Thus, by making the width R2 larger than the width R1, the width of the oxide 230b is made larger than the width of the oxide 230a. That is, the channel width of the transistor 200b can be made larger than the channel width of the transistor 200a. By increasing the channel width, the on-state current can be increased. For example, by increasing the width R2, the on-state current of the transistor 200b functioning as a read transistor is increased, whereby a memory cell and a semiconductor device with high reading speed can be achieved.

Note that in the structure illustrated in FIG. 5A to FIG. 5D, the second opening provided with the oxide 230b and the insulator 250b is not filled with them in some cases depending on the thickness of an insulating film to be the insulator 250a and the insulator 250b and the thickness of an oxide film to be the oxide 230a and the oxide 230b. The oxide 230b has a depressed portion reflecting the shape of the second opening in some cases. In that case, an insulator is preferably provided in a region between the oxide 230b and the conductor 246.

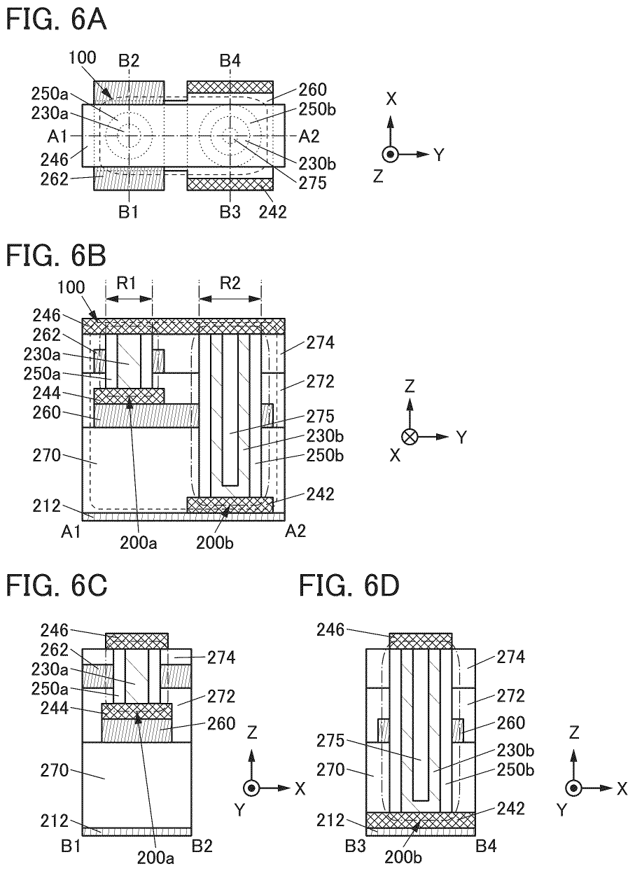

A modification example of the memory cell 100 illustrated in FIG. 5A to FIG. 5D is illustrated in FIG. 6A to FIG. 6D. FIG. 6A is a top view of the memory cell 100. FIG. 6B is a cross-sectional view of the memory cell 100, and is a cross-sectional view of a portion indicated by the dashed-dotted line A1-A2 in FIG. 6A. FIG. 6C is a cross-sectional view of the memory cell 100, and is a cross-sectional view of a portion indicated by the dashed-dotted line B1-B2 in FIG. 6A. FIG. 6D is a cross-sectional view of the memory cell 100, and is a cross-sectional view of a portion indicated by the dashed-dotted line B3-B4 in FIG. 6A. Note that for clarity of the drawing, some components are omitted in the top view of FIG. 6A.

In the memory cell 100 illustrated in FIG. 6A to FIG. 6D, an insulator 275 is provided in a region surrounded by the oxide 230b and the conductor 246. The insulator 275 is provided to fill the depressed portion of the oxide 230b. The insulator 275 includes a region in contact with the top surface of the oxide 230b. For the insulator 275, an insulating material usable for the insulator 212, the insulator 250, or the like can be used. Provision of the insulator 275 can inhibit the conductor 246 from being formed in the depressed portion of the oxide 230b.

Note that depending on the width (the length in the A1-A2 direction) of the depressed portion of the oxide 230b, the formation method of the conductor 246, or the like, the conductor 246 is not formed in the depressed portion of the oxide 230b in some cases even when the insulator 275 is not provided in the depressed portion of the oxide 230b. Examples of such a case include a case where the width (the length in the A1-A2 direction) of the depressed portion of the oxide 230b is small. In this case, the region between the oxide 230b and the conductor 246 is a gap. The gap contains, for example, one or more selected from air, nitrogen, oxygen, carbon dioxide, and Group 18 elements (typified by helium, neon, argon, xenon, krypton, and the like).

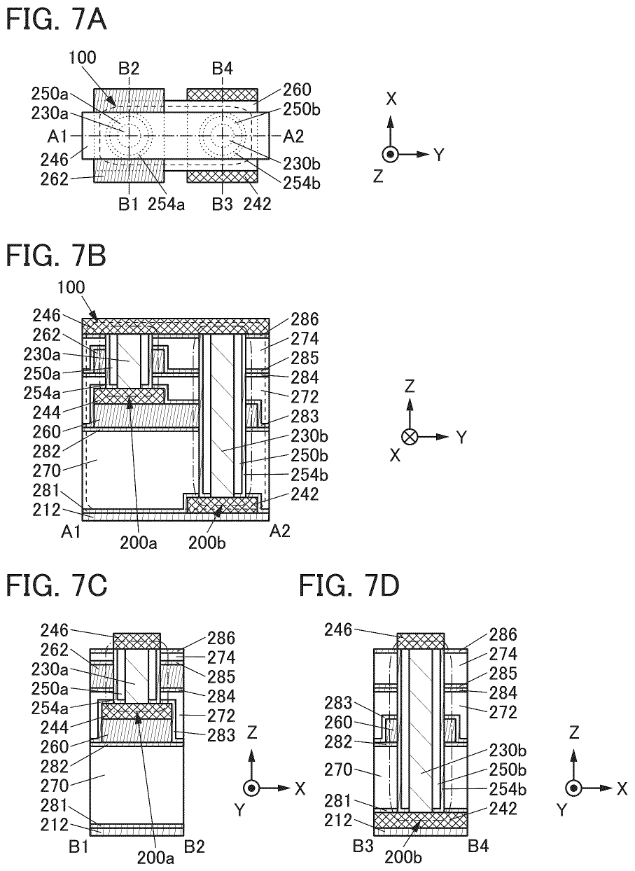

Another modification example of the memory cell 100 illustrated in FIG. 2A to FIG. 2D is illustrated in FIG. 7A to FIG. 7D. FIG. 7A is atop view of the memory cell 100. FIG. 7B is a cross-sectional view of the memory cell 100, and is a cross-sectional view of a portion indicated by the dashed-dotted line A1-A2 in FIG. 7A. FIG. 7C is a cross-sectional view of the memory cell 100, and is a cross-sectional view of a portion indicated by the dashed-dotted line B1-B2 in FIG. 7A. FIG. 7D is a cross-sectional view of the memory cell 100, and is a cross-sectional view of a portion indicated by the dashed-dotted line B3-B4 in FIG. 7A. Note that for clarity of the drawing, some components are omitted in the top view of FIG. 7A.

As illustrated in FIG. 7B and FIG. 7C, an insulator 254a having a barrier property against oxygen is preferably provided between the conductor 262 and the insulator 250a. Provision of the insulator 254a can inhibit oxygen contained in the insulator 250a from diffusing into the conductor 262. That is, a reduction in the amount of oxygen supplied to the oxide 230a can be inhibited. In addition, oxidation of the conductor 262 due to oxygen contained in the insulator 250a can be inhibited. Moreover, formation of the insulator 263 illustrated in FIG. 3B and FIG. 3C can be inhibited.

As illustrated in FIG. 7B and FIG. 7D, an insulator 254b having a barrier property against oxygen is preferably provided between the conductor 260 and the insulator 250b. Provision of the insulator 254b can inhibit oxygen contained in the insulator 250b from diffusing into the conductor 260. That is, a reduction in the amount of oxygen supplied to the oxide 230b can be inhibited. In addition, oxidation of the conductor 260 due to oxygen contained in the insulator 250b can be inhibited. Moreover, formation of the insulator 261 illustrated in FIG. 3B and FIG. 3D can be inhibited.

As each of the insulator 254a and the insulator 254b, the above-described insulator having a barrier property against oxygen is preferably used. The insulator 254a and the insulator 254b are formed in the same step. Thus, the insulator 254a and the insulator 254b contain the same insulating material. In addition, the thickness of the insulator 254a is equal to the thickness of the insulator 254b.

The above-described insulator having a barrier property against oxygen is preferably provided between the conductor and the insulator containing oxygen. When an insulator having a barrier property against oxygen is provided between the conductor and the insulator containing oxygen, diffusion of oxygen contained in the insulator into the conductor can be inhibited. That is, a reduction in the amount of oxygen supplied to the oxide 230 can be inhibited. In addition, oxidation of the conductor due to oxygen contained in the insulator can be inhibited.

For example, in the memory cell 100 illustrated in FIG. 7A to FIG. 7D, an insulator 281 is provided between the conductor 242 and the insulator 270. An insulator 282 is provided between the conductor 260 and the insulator 270. An insulator 283 is provided between the conductors 244 and 260 and the insulator 272. An insulator 284 is provided between the conductor 262 and the insulator 272. An insulator 285 is provided between the conductor 262 and the insulator 274. An insulator 286 is provided between the conductor 246 and the insulator 274. The insulator 281 to the insulator 286 are insulators having a barrier property against oxygen.

Note that the memory cell 100 does not necessarily include all of the insulator 281 to the insulator 286. Examples of such a case include a case where a conductive material that is not easily oxidized or a conductive material having a function of inhibiting diffusion of oxygen is used for the conductor included in the memory cell 100. Thus, one or more of the insulator 281 to the insulator 286 are preferably provided.

FIG. 2A illustrates a structure in which the conductor 246 is provided to extend in the Y direction. Note that the present invention is not limited thereto as long as the direction in which the conductor 246 extends is different from the direction in which the conductor 262 and the conductor 242 extend.

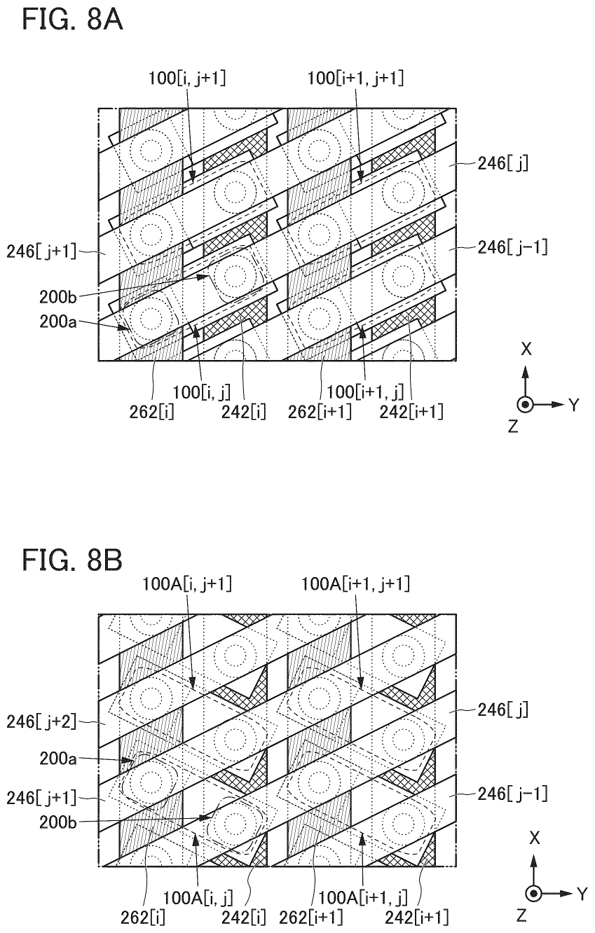

Another modification example of the memory cell 100 illustrated in FIG. 2A is illustrated in FIG. 8A. FIG. 8A is a top view of a semiconductor device including the memory cell 100. Note that FIG. 8A illustrates a region including the memory cell 100[i,j], a memory cell 100[i+1,j], a memory cell 100[i,j+1], and a memory cell 100[i+1,j+1].

For example, as illustrated in FIG. 8A, the conductor 262 and the conductor 242 may extend in the X direction, and the conductor 246 may extend obliquely in the X direction. In this case, in the plan view, a line segment connecting the transistor 200a and the transistor 200b included in one memory cell 100 is parallel to the direction in which the conductor 246 extends. In other words, in the plan view, a line segment connecting the center of the first opening and the center of the second opening included in one memory cell 100 is parallel to the direction in which the conductor 246 extends. That is, the number of conductors 246 connected to one memory cell 100 is one.

As illustrated in FIG. 8A, the transistors 200 are arranged in the Y direction in a zigzag manner. For example, the transistor 200a and the transistor 200b included in the memory cell 100[i,j] and the transistor 200a and the transistor 200b included in the memory cell 100[i+1,j] are arranged in the Y direction in a zigzag manner.

With the structure illustrated in FIG. 8A, the memory density of the semiconductor device can be further increased in some cases.

Note that some of the structures described in [Memory cell 100] and [Modification example of memory cell 100] may be applied to a memory cell described below.

### [Memory Cell 100A]

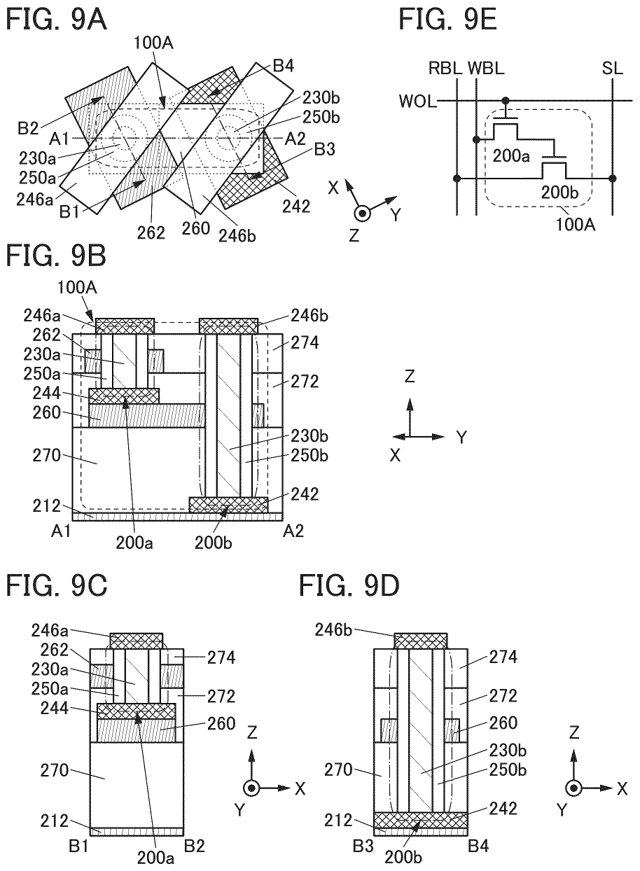

FIG. 8B and FIG. 9A to FIG. 9D illustrate structure examples different from that of the above-described memory cell 100. Note that in a memory cell described below, components having the same functions as the components included in the above-described memory cell 100 are denoted by the same reference numerals. Differences from the above-described memory cell 100 are mainly described below, and common portions are not described.

FIG. 8B is atop view of a semiconductor device including a memory cell 100A. Note that FIG. 8B illustrates a region including a memory cell 100A[i,j], a memory cell 100A[i+1,j], a memory cell 100A[i,j+1], and a memory cell 100A[i+1,j+1].

The memory cell 100A is different from the memory cell 100 illustrated in FIG. 8A in that a line segment connecting the transistor 200a and the transistor 200b is not parallel to the direction in which the conductor 246 extends. In other words, the memory cell 100A is different from the memory cell 100 illustrated in FIG. 8A in that the number of conductors 246 connected to one memory cell 100A is two.

As illustrated in FIG. 8B, the memory cell 100A[i,j] is connected to each of the conductor 246[ ] and a conductor 246[j+1]. Specifically, the transistor 200a included in the memory cell 100A[i,j] is connected to the conductor 246[j+1], and the transistor 200b included in the memory cell 100A[i,j] is connected to the conductor 246[ ]. That is, in this structure, the conductor 246 connected to the transistor 200a and the conductor 246 connected to the transistor 200b are different from each other.

FIG. 9A is a top view of the memory cell 100A. FIG. 9B is a cross-sectional view of the memory cell 100A, and is a cross-sectional view of a portion indicated by the dashed-dotted line A1-A2 in FIG. 9A. FIG. 9C is a cross-sectional view of the memory cell 100A, and is a cross-sectional view of a portion indicated by the dashed-dotted line B1-B2 in FIG. 9A. FIG. 9D is a cross-sectional view of the memory cell 100A, and is a cross-sectional view of a portion indicated by the dashed-dotted line B3-B4 in FIG. 9A. Note that for clarity of the drawing, some components are omitted in the top view of FIG. 9A.

The memory cell 100A is different from the memory cell 100 illustrated in FIG. 2A to FIG. 2D in including a conductor 246a and a conductor 246b instead of the conductor 246.

The conductor 246a is electrically connected to the oxide 230a, and the conductor 246b is electrically connected to the oxide 230b. Specifically, the conductor 246a includes a region in contact with the top surface of the oxide 230a, and the conductor 246b includes a region in contact with the top surface of the oxide 230b. The direction in which the conductor 246a extends is parallel to the direction in which the conductor 246b extends. The direction in which the conductor 246a extends is different from the direction in which the conductor 262 extends. The direction in which the conductor 246b extends is different from the direction in which the conductor 242 extends.

The conductor 246a has a function of the other of the source electrode and the drain electrode of the transistor 200a and a function of a wiring. The conductor 246b has a function of the other of the source electrode and the drain electrode of the transistor 200b and a function of a wiring.

As illustrated in FIG. 9B, the conductor 246a and the conductor 246b are preferably provided in the same layer. The conductor 246a is preferably formed using the same material in the same step as the conductor 246b. In that case, the conductor 246a and the conductor 246b contain the same conductive material. When the conductor 246a is formed using the same material in the same step as the conductor 246b, the semiconductor device including the memory cell 100A can be manufactured without increasing the number of steps.

For example, in the case where the conductor 246[j+1] illustrated in FIG. 8B is the conductor 246a, the conductor 246b corresponds to the conductor 246[ ] illustrated in FIG. 8B. For another example, in the case where the conductor 246[j+1] illustrated in FIG. 8B is the conductor 246b, the conductor 246b corresponds to a conductor 246[j+2] illustrated in FIG. 8B.

The semiconductor device including the memory cell 100A can be used as a storage device. FIG. 9E illustrates a circuit diagram of the semiconductor device including the memory cell 100A, which is used as a storage device. The memory cell 100A includes the transistor 200a and the transistor 200b.

As illustrated in FIG. 9E, the gate of the transistor 200a is electrically connected to the wiring WOL, one of the source and the drain of the transistor 200a is electrically connected to the gate of the transistor 200b, and the other of the source and the drain of the transistor 200a is electrically connected to a wiring WBL. One of the source and the drain of the transistor 200b is electrically connected to the wiring SL, and the other of the source and the drain of the transistor 200b is electrically connected to a wiring RBL.

The wiring WBL functions as a write bit line, and the wiring RBL functions as a read bit line.

The wiring WOL corresponds to the conductor 262, the wiring WBL corresponds to the conductor 246a, the wiring RBL corresponds to the conductor 246b, and the wiring SL corresponds to the conductor 242. That is, the conductor 262 includes a region functioning as a word line, the conductor 246a includes a region functioning as a write bit line, the conductor 246b includes a region functioning as a read bit line, and the conductor 242 includes a region functioning as a selection line.

Note that one of the source and the drain of the transistor 200b may be electrically connected to the wiring RBL, and the other of the source and the drain of the transistor 200b may be electrically connected to the wiring SL. In this case, the wiring RBL corresponds to the conductor 242, and the wiring SL corresponds to the conductor 246b. That is, the conductor 242 includes a region functioning as a read bit line, and the conductor 246b includes a region functioning as a selection line.

With the above structure, the write bit line and the read bit line of the memory cell can be independent from each other.

Note that the structure of the memory cell and the storage device including the memory cell will be described in Embodiment 2.

### [Memory Cell 100B]

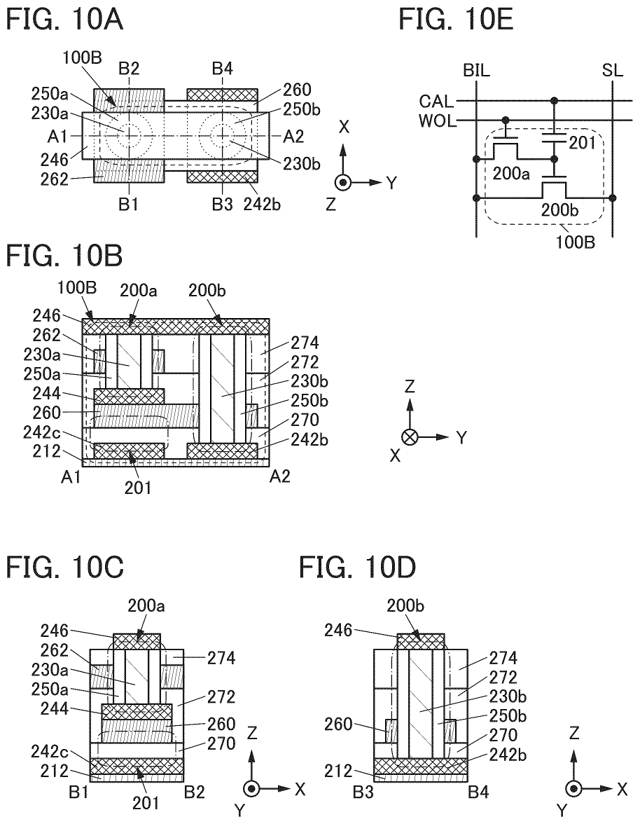

FIG. 10A to FIG. 10D illustrate a structure example different from that of the above-described memory cell 100. Note that in a memory cell described below, components having the same functions as the components included in the above-described memory cell 100 are denoted by the same reference numerals. Differences from the above-described memory cell 100 are mainly described below, and common portions are not described.

FIG. 10A is a top view of a memory cell 100B. FIG. 10B is a cross-sectional view of the memory cell 100B, and is a cross-sectional view of a portion indicated by the dashed-dotted line A1-A2 in FIG. 10A. FIG. 10C is a cross-sectional view of the memory cell 100B, and is a cross-sectional view of a portion indicated by the dashed-dotted line B1-B2 in FIG. 10A. FIG. 10D is a cross-sectional view of the memory cell 100B, and is a cross-sectional view of a portion indicated by the dashed-dotted line B3-B4 in FIG. 10A. Note that for clarity of the drawing, some components are omitted in the top view of FIG. 10A.

The memory cell 100B is different from the memory cell 100 illustrated in FIG. 2A to FIG. 2D in including a capacitor 201 below the transistor 200a. The memory cell 100B includes the transistor 200a, the transistor 200b, and the capacitor 201.

The memory cell 100B is different from the memory cell 100 illustrated in FIG. 2A to FIG. 2D in including a conductor 242c. Note that in FIG. 10A to FIG. 10D, an identification sign is added to the conductor 242 functioning as one of the source electrode and the drain electrode of the transistor 200b. Specifically, a conductor functioning as one of the source electrode and the drain electrode of the transistor 200b is denoted as a conductor 242b. Thus, for the conductor 242b, the description of the conductor 242 described in [Memory cell 100] above can be referred to.

The capacitor 201 includes the conductor 242c, the insulator 270 over the conductor 242c, and the conductor 260 over the insulator 270. The conductor 242c includes a region functioning as one electrode of the capacitor 201, the conductor 260 includes a region functioning as the other electrode of the capacitor 201, and the insulator 270 includes a region functioning as a dielectric of the capacitor 201. The capacitor 201 forms a MIM (Metal-Insulator-Metal) capacitor.

The conductor 242c is provided over the insulator 212. The conductor 242c includes a region overlapping with the conductor 260 with the insulator 270 therebetween. The conductor 242c is provided to extend in the X direction. That is, the direction in which the conductor 242c extends is parallel to the direction in which the conductor 242b extends. The conductor 242c has a function of a wiring.

As illustrated in FIG. 10B, the conductor 242c and the conductor 242b are preferably provided in the same layer. The conductor 242c is preferably formed using the same material in the same step as the conductor 242b. In that case, the conductor 242c and the conductor 242b contain the same conductive material. When the conductor 242c is formed using the same material in the same step as the conductor 242b, the capacitor can be formed without increasing the number of steps in the manufacturing process of the semiconductor device.

As described above, the channel length of the transistor 200b is longer than the channel length of the transistor 200a. Thus, the transistor 200b has larger channel capacitance (capacitance between the gate electrode and the channel formation region) than the transistor 200a. Thus, the capacitor 201 may have small capacitance.

The semiconductor device including the memory cell 100B can be used as a storage device. FIG. 10E illustrates a circuit diagram of the semiconductor device including the memory cell 100B, which is used as a storage device. The memory cell 100B includes the transistor 200a, the transistor 200b, and the capacitor 201. That is, the memory cell 100B can be regarded as a memory cell composed of two transistors and one capacitor. A memory cell composed of two transistors and one capacitor is also referred to as a 2Tr1C memory cell. Thus, the memory cell 100B is a 2Tr1C memory cell.

As illustrated in FIG. 10E, the gate of the transistor 200a is electrically connected to the wiring WOL, one of the source and the drain of the transistor 200a is electrically connected to one electrode of the capacitor 201, and the other of the source and the drain of the transistor 200a is electrically connected to the wiring BIL. The gate of the transistor 200b is electrically connected to the one electrode of the capacitor 201, one of the source and the drain of the transistor 200b is electrically connected to the wiring SL, and the other of the source and the drain of the transistor 200b is electrically connected to the wiring BIL. The other electrode of the capacitor 201 is electrically connected to a wiring CAL.

The wiring CAL functions as a capacitor line.

The wiring WOL corresponds to the conductor 262, the wiring BIL corresponds to the conductor 246, the wiring SL corresponds to the conductor 242b, and the wiring CAL corresponds to the conductor 242c. That is, the conductor 262 includes a region functioning as a word line, the conductor 246 includes a region functioning as a bit line, the conductor 242b includes a region functioning as a selection line, and the conductor 242c includes a region functioning as a capacitor line.

Note that the structure of the memory cell and the storage device including the memory cell will be described in Embodiment 2.

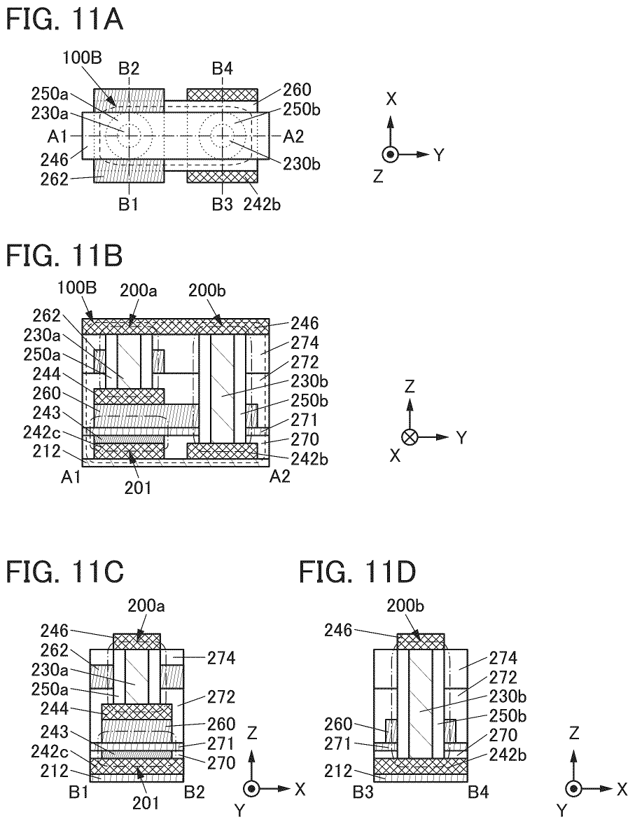

Here, a modification example of the memory cell 100B illustrated in FIG. 10A to FIG. 10D is illustrated in FIG. 11A to FIG. 11D. FIG. 11A is a top view of the memory cell 100B. FIG. 11B is a cross-sectional view of the memory cell 100B, and is a cross-sectional view of a portion indicated by the dashed-dotted line A1-A2 in FIG. 11A. FIG. 11C is a cross-sectional view of the memory cell 100B, and is a cross-sectional view of a portion indicated by the dashed-dotted line B1-B2 in FIG. 11A. FIG. 11D is a cross-sectional view of the memory cell 100B, and is a cross-sectional view of a portion indicated by the dashed-dotted line B3-B4 in FIG. 11A. Note that for clarity of the drawing, some components are omitted in the top view of FIG. 11A.

As illustrated in FIG. 11A to FIG. 11D, the memory cell 100B may further include a conductor 243. The conductor 243 is provided over the conductor 242c and includes a region overlapping with the conductor 260. In this case, the conductor 243 functions as one electrode of the capacitor 201, and the conductor 242c functions as a wiring. Provision of the conductor 243 can shorten the distance between the pair of electrodes of the capacitor 201. Thus, the capacitance of the capacitor 201 can be increased. The conductor functioning as the one electrode of the capacitor 201 and the conductor functioning as a wiring are separated from each other, whereby a semiconductor device can be manufactured using materials suitable for the respective conductors.

FIG. 11B illustrates a structure in which an end portion of the conductor 243 in the Y direction is aligned with an end portion of the conductor 242 in the Y direction. Note that the present invention is not limited thereto. The end portion of the conductor 243 in the Y direction may be positioned inside the end portion of the conductor 242 in the Y direction, for example.

FIG. 1C illustrates a structure in which an end portion of the conductor 243 in the X direction is aligned with an end portion of the conductor 260 in the X direction. Note that the present invention is not limited thereto. The end portion of the conductor 243 in the X direction may be positioned inside the end portion of the conductor 260 in the X direction, or may be positioned outside the end portion of the conductor 260 in the X direction, for example.

As illustrated in FIG. 11B to FIG. 11D, an insulator 271 may be provided over the insulator 270. The insulator 271 is provided between the pair of electrodes of the capacitor 201 and includes a region functioning as a dielectric of the capacitor 201. In FIG. 11B to FIG. 1 ID, the insulator 271 is provided between the conductor 243 and the conductor 260.

For the insulator 271, a high permittivity (high-k) material (material with a high relative permittivity) is preferably used. Examples of the high permittivity (high-k) material include an oxide, an oxynitride, a nitride oxide, and a nitride containing one or more kinds of metal elements selected from aluminum, hafnium, zirconium, gallium, and the like. The above oxide, oxynitride, nitride oxide, and nitride may contain silicon. Stacked insulators formed of any of the above materials can also be used.

Specifically, as the high permittivity (high-k) material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium are given. When an insulator formed of such a high-k material is used, the insulator 271 can be made thick enough to inhibit leakage current and a sufficiently high capacitance of the capacitor 201 can be ensured.

It is preferable to use stacked insulators formed of any of the above-described materials, and it is preferable to use a stacked-layer structure of a high permittivity (high-k) material and a material having a higher dielectric strength than the high permittivity (high-k) material. As the insulator 271, an insulator in which zirconium oxide, aluminum oxide, and zirconium oxide are stacked in this order can be used, for example. As another example, an insulator in which zirconium oxide, aluminum oxide, zirconium oxide, and aluminum oxide are stacked in this order can be used. As another example, an insulating film in which hafnium zirconium oxide, aluminum oxide, hafnium zirconium oxide, and aluminum oxide are stacked in this order can be used. The use of such stacked insulators with relatively high dielectric strength, such as aluminum oxide, can increase the dielectric strength and inhibit electrostatic breakdown of the capacitor 201.

Although FIG. 11A to FIG. 11D illustrate a structure in which the conductor 243 and the insulator 271 are provided, the present invention is not limited thereto. The memory cell 100B may include one of the conductor 243 and the insulator 271.

### [Memory Cell 100C]

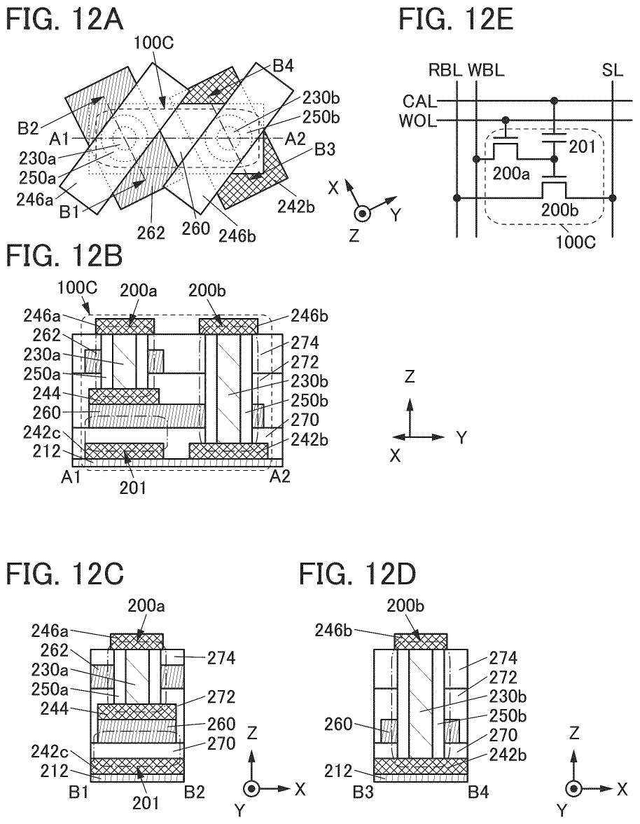

FIG. 12A to FIG. 12D illustrate a structure example different from those of the memory cell 100A and the memory cell 100B that are described above. Note that in a memory cell described below, components having the same functions as the components included in the memory cell 100A and the memory cell 100B that are described above are denoted by the same reference numerals. Differences from the memory cell 100A and the memory cell 100B that are described above are mainly described below, and common portions are not described.

FIG. 12A is a top view of a memory cell 100C. FIG. 12B is a cross-sectional view of the memory cell 100C, and is a cross-sectional view of a portion indicated by the dashed-dotted line A1-A2 in FIG. 12A. FIG. 12C is a cross-sectional view of the memory cell 100C, and is a cross-sectional view of a portion indicated by the dashed-dotted line B1-B2 in FIG. 12A. FIG. 12D is a cross-sectional view of the memory cell 100C, and is a cross-sectional view of a portion indicated by the dashed-dotted line B3-B4 in FIG. 12A. Note that for clarity of the drawing, some components are omitted in the top view of FIG. 12A.

The memory cell 100C is different from the memory cell 100A illustrated in FIG. 9A to FIG. 9D in including the capacitor 201 below the transistor 200a. Thus, the memory cell 100C can be regarded as a modification example of the memory cell 100A illustrated in FIG. 9A to FIG. 9D. The memory cell 100C includes the transistor 200a, the transistor 200b, and the capacitor 201. Thus, the memory cell 100C is a 2Tr1C memory cell.

The memory cell 100C is different from the memory cell 100B illustrated in FIG. 10A to FIG. 10D in including the conductor 246a and the conductor 246b instead of the conductor 246. Thus, the memory cell 100C can be regarded as a modification example of the memory cell 100B illustrated in FIG. 10A to FIG. 10D.

For the details of the structure examples of the transistor 200a and the transistor 200b, the description in [Memory cell 100A] above can be referred to. For the details of the structure example of the capacitor 201, the description in [Memory cell 100B] above can be referred to.

The semiconductor device including the memory cell 100C can be used as a storage device. FIG. 12E illustrates a circuit diagram of the semiconductor device including the memory cell 100C, which is used as a storage device. The memory cell 100C includes the transistor 200a, the transistor 200b, and the capacitor 201.

As illustrated in FIG. 12E, the gate of the transistor 200a is electrically connected to the wiring WOL, one of the source and the drain of the transistor 200a is electrically connected to one electrode of the capacitor 201, and the other of the source and the drain of the transistor 200a is electrically connected to the wiring WBL. The gate of the transistor 200b is electrically connected to the one electrode of the capacitor 201, one of the source and the drain of the transistor 200b is electrically connected to the wiring SL, and the other of the source and the drain of the transistor 200b is electrically connected to the wiring RBL. The other electrode of the capacitor 201 is electrically connected to the wiring CAL.

The wiring WOL corresponds to the conductor 262, the wiring WBL corresponds to the conductor 246a, the wiring RBL corresponds to the conductor 246b, the wiring SL corresponds to the conductor 242b, and the wiring CAL corresponds to the conductor 242c. That is, the conductor 262 includes a region functioning as a word line, the conductor 246a includes a region functioning as a write bit line, the conductor 246b includes a region functioning as a read bit line, the conductor 242b includes a region functioning as a selection line, and the conductor 242c includes a region functioning as a capacitor line.

Note that one of the source and the drain of the transistor 200b may be electrically connected to the wiring RBL, and the other of the source and the drain of the transistor 200b may be electrically connected to the wiring SL. In this case, the wiring RBL corresponds to the conductor 242, and the wiring SL corresponds to the conductor 246b. That is, the conductor 242 includes a region functioning as a read bit line, and the conductor 246b includes a region functioning as a selection line.

Note that the structure of the memory cell and the storage device including the memory cell will be described in Embodiment 2.

### [Memory Cell 100D]

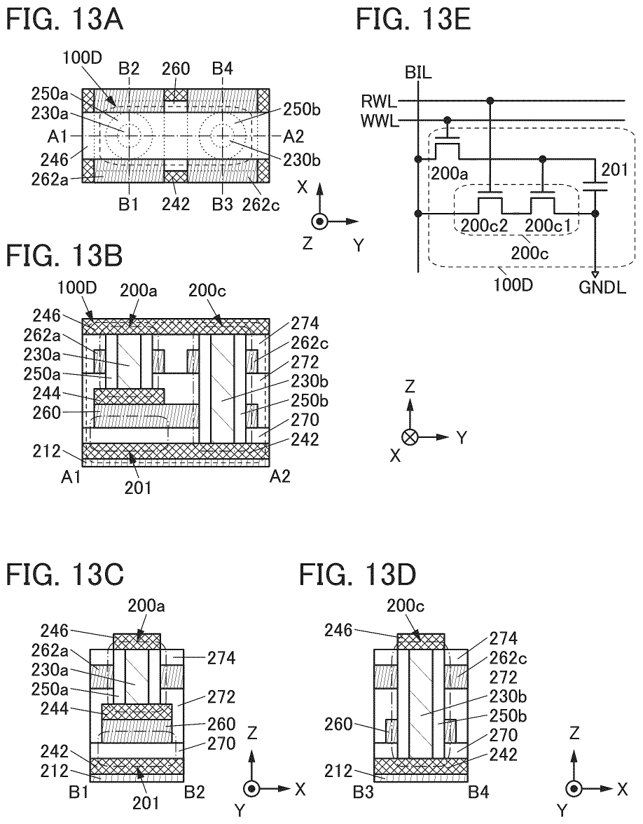

FIG. 13A to FIG. 13D illustrate a structure example different from that of the above-described memory cell 100B. Note that in a memory cell described below, components having the same functions as the components included in the above-described memory cell 100B are denoted by the same reference numerals. Differences from the above-described memory cell 100B are mainly described below, and common portions are not described.

FIG. 13A is a top view of a memory cell 100D. FIG. 13B is a cross-sectional view of the memory cell 100D, and is a cross-sectional view of a portion indicated by the dashed-dotted line A1-A2 in FIG. 13A. FIG. 13C is a cross-sectional view of the memory cell 100D, and is a cross-sectional view of a portion indicated by the dashed-dotted line B1-B2 in FIG. 13A. FIG. 13D is a cross-sectional view of the memory cell 100D, and is a cross-sectional view of a portion indicated by the dashed-dotted line B3-B4 in FIG. 13A. Note that for clarity of the drawing, some components are omitted in the top view of FIG. 13A.

The memory cell 100D is different from the memory cell 100B illustrated in FIG. 10A to FIG. 10D in including a transistor 200c instead of the transistor 200b. The memory cell 100D includes the transistor 200a, the transistor 200c, and the capacitor 201.

The memory cell 100D is different from the memory cell 100B illustrated in FIG. 10A to FIG. 10D in including a conductor 262c between the conductor 260 and the conductor 246. Note that in FIG. 13A to FIG. 13D, an identification sign is added to the conductor 262 functioning as the gate electrode of the transistor 200a. Specifically, a conductor functioning as the gate electrode of the transistor 200a is denoted as a conductor 262a. Thus, for the conductor 262a, the description of the conductor 262 described in [Memory cell 100] above can be referred to.

The transistor 200c includes the conductor 242, the conductor 260 above the conductor 242, the conductor 262c above the conductor 260, the conductor 246 above the conductor 262c, the oxide 230b, and the insulator 250b. The insulator 272 includes a region positioned between the conductor 260 and the conductor 262c, and the insulator 274 includes a region positioned between the conductor 262c and the conductor 246.

An opening reaching the conductor 242 is provided in the insulator 270, the conductor 260, the insulator 272, the conductor 262c, and the insulator 274. The insulator 250b and the oxide 230b are placed inside the opening. The insulator 250b includes a region in contact with the side surface of the oxide 230b, a region in contact with the side surface of the conductor 260, a region in contact with the side surface of the conductor 262c, a region in contact with at least part of the side surface of the insulator 270, a region in contact with at least part of the side surface of the insulator 272, and a region in contact with at least part of the side surface of the insulator 274. The oxide 230b includes a region in contact with the side surface of the insulator 250b, a region in contact with at least part of the top surface of the conductor 242, and a region in contact with at least part of the bottom surface of the conductor 246.

The conductor 260 includes a region functioning as a first gate electrode of the transistor 200c. The conductor 262c includes a region functioning as a second gate electrode of the transistor 200c. The insulator 250b includes a region functioning as a gate insulator of the transistor 200c. The conductor 242 includes a region functioning as one of a source electrode and a drain electrode of the transistor 200c. The conductor 246 includes a region functioning as the other of the source electrode and the drain electrode of the transistor 200c. The region of the oxide 230b that faces the conductor 260 with the insulator 250b therebetween and the region of the oxide 230b that faces the conductor 262c with the insulator 250b therebetween function as channel formation regions of the transistor 200c.

The conductor 260 and the conductor 262c may be electrically connected to each other so that the conductor 262c and the conductor 260 have the same potential. In this case, the transistor 200c can be regarded as a double-gate transistor. Note that in this specification and the like, a double-gate transistor refers to a transistor in which two gates are included and the two gates are electrically connected to each other. With use of a double-gate transistor, a larger amount of current can flow. Thus, the on-state current of the transistor 200c functioning as a read transistor is increased, whereby a memory cell and a semiconductor device with high reading speed can be achieved.

Note that in the case where the conductor 260 and the conductor 262c are electrically connected to each other in the structure illustrated in FIG. 13A to FIG. 13D, the conductor 242b and the conductor 242c illustrated in FIG. 10A to FIG. 10D are preferably provided instead of the conductor 242. Accordingly, a memory cell having the circuit structure illustrated in FIG. 10E can be formed. In this case, the transistor 200b illustrated in FIG. 10E is a double-gate transistor.

Considering the above structure, the conductor 262a and the conductor 262c illustrated in FIG. 13A to FIG. 13D may be provided instead of the conductor 262 in the memory cell 100B illustrated in FIG. 10A to FIG. 10D. In this structure, the conductor 260 and the conductor 262c are electrically connected to each other, whereby the memory cell 100B including the transistor 200b having a double-gate structure can be formed.

Alternatively, the potential of the conductor 262c may be changed not in conjunction with but independently from the potential of the conductor 260. In this case, the transistor 200c can be regarded as having a structure in which two transistors are connected in series. That is, the memory cell 100D can be regarded as a memory cell composed of three transistors and one capacitor. A memory cell composed of three transistors and one capacitor is also referred to as a 3Tr1C memory cell. Thus, the memory cell 100D is a 3Tr1C memory cell.

Note that in the case where the potential of the conductor 262c is changed not in conjunction with but independently from the potential of the conductor 260, the conductor 262c includes a region functioning as a wiring. In this case, the direction in which the conductor 262c extends and the direction in which the conductor 246 extends are preferably different, and are further preferably orthogonal to each other. The direction in which the conductor 262a extends is the same as the direction in which the conductor 262c extends.

As illustrated in FIG. 13B, the conductor 262c and the conductor 262a are preferably provided in the same layer. The conductor 262c is preferably formed using the same material in the same step as the conductor 262a. In that case, the conductor 262c and the conductor 262a contain the same conductive material. When the conductor 262c is formed using the same material in the same step as the conductor 262a, the second gate electrode can be formed without increasing the number of steps in the manufacturing process of the semiconductor device.

The semiconductor device including the memory cell 100D can be used as a storage device. FIG. 13E illustrates a circuit diagram of the semiconductor device including the memory cell 100D, which is used as a storage device. The memory cell 100D includes the transistor 200a, the transistor 200c, and the capacitor 201. Note that the transistor 200c includes a transistor 200c1 and a transistor 200c2 that are connected in series.

In the case where the transistor 200c includes the transistor 200c1 and the transistor 200c2 that are connected in series, the conductor 260 includes a region functioning as a gate electrode of the transistor 200c1, and the conductor 262c includes a region functioning as a gate electrode of the transistor 200c2. The insulator 250b includes a region functioning as a gate insulator of the transistor 200c1 and a region functioning as a gate insulator of the transistor 200c2. The conductor 242 includes a region functioning as one of a source electrode and a drain electrode of the transistor 200c1, and the conductor 246 includes a region functioning as the other of a source electrode and a drain electrode of the transistor 200c2.

As illustrated in FIG. 13E, the gate of the transistor 200a is electrically connected to a wiring WWL, one of the source and the drain of the transistor 200a is electrically connected to one electrode of the capacitor 201, and the other of the source and the drain of the transistor 200a is electrically connected to the wiring BIL. The gate of the transistor 200c1 is electrically connected to the one electrode of the capacitor 201, one of the source and the drain of the transistor 200c1 is electrically connected to a wiring GNDL, and the other of the source and the drain of the transistor 200c1 is electrically connected to one of the source electrode and the drain electrode of the transistor 200c2. The gate of the transistor 200c2 is electrically connected to a wiring RWL, and the other of the source and the drain of the transistor 200c2 is electrically connected to the wiring BIL. The other electrode of the capacitor 201 is electrically connected to the wiring GNDL.

The wiring WWL functions as a write word line, the wiring RWL functions as a read word line, and the wiring GNDL functions as a wiring supplying a low-level potential.

The wiring WWL corresponds to the conductor 262a, the wiring RWL corresponds to the conductor 262c, the wiring BIL corresponds to the conductor 246, and the wiring GNDL corresponds to the conductor 242. That is, the conductor 262a includes a region functioning as a write word line, the conductor 262c includes a region functioning as a read word line, the conductor 246 includes a region functioning as a bit line, and the conductor 242 includes a region functioning as a wiring supplying a low-level potential.

Note that the structure of the memory cell and the storage device including the memory cell will be described in Embodiment 2.

### [Component Material of Semiconductor Device]

Component materials that can be used for the semiconductor device are described below.

### <<Substrate>>

As a substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. In contrast, when a material having a low relative permittivity is used for the insulator functioning as an interlayer film, parasitic capacitance generated between wirings can be reduced. Thus, a material is preferably selected depending on the function of an insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. In addition, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. An indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon is added may be used. An indium gallium zinc oxide containing nitrogen may be used. With use of such a material, hydrogen contained in the metal oxide where the channel is formed can be captured in some cases. Alternatively, hydrogen entering from an external insulator or the like can be captured in some cases.

### [Example of Method for Manufacturing Semiconductor Device]

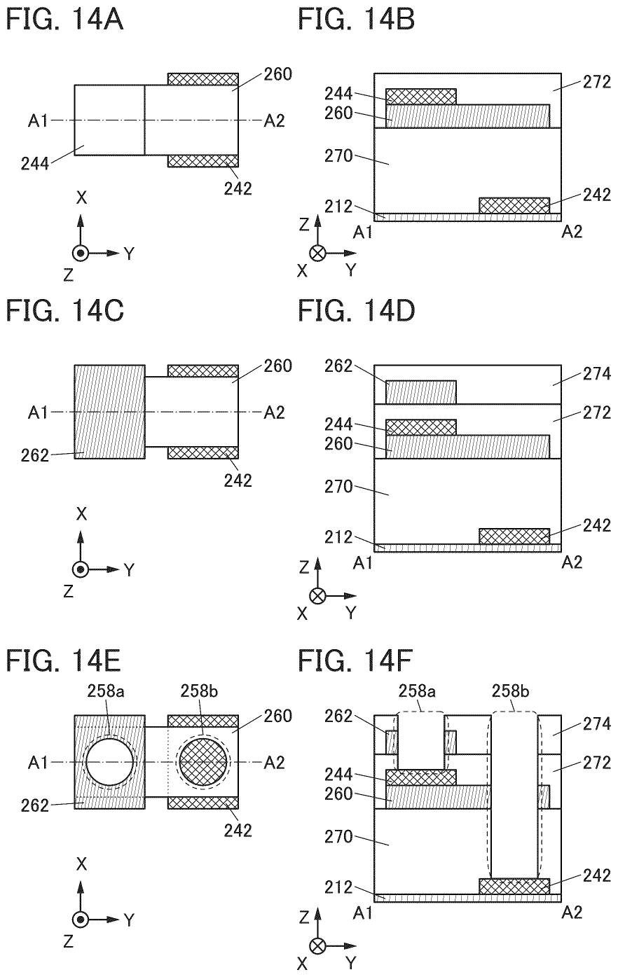

Next, a method for manufacturing the semiconductor device including the memory cell 100 illustrated in FIG. 2A to FIG. 2D is described with reference to FIG. 14A to FIG. 16D.

In FIG. 14A to FIG. 16D, A, C, and E of each drawing are top views. Moreover, B, D, and F of each drawing are cross-sectional views corresponding to a portion indicated by the dashed-dotted line A1-A2 in A, C, and E of each drawing. Note that for clarity of the drawing, some components are omitted in the top views of A, C, and E of each drawing.

Hereinafter, a film of an insulating material for forming an insulator, a film of a conductive material for forming a conductor, or a film of a semiconductor material for forming a semiconductor can be formed by a plating method, a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used. Examples of a DC sputtering method include a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving charge from plasma. In that case, accumulated charge may break the wiring, the electrode, the element, or the like included in the semiconductor device. In contrast, such plasma damage is not caused in the case of a thermal CVD method, which does not use plasma, and thus the yield of the semiconductor device can be increased. In addition, a thermal CVD method does not cause plasma damage during film formation, so that a film with few defects can be obtained.

As an ALD method, a thermal ALD method, a PEALD method, or the like can be used.

A CVD method and an ALD method are different from a sputtering method in which particles ejected from a target or the like are deposited. Thus, a CVD method and an ALD method are film formation methods that enable favorable step coverage almost regardless of the shape of an object. In particular, an ALD method enables excellent step coverage and excellent thickness uniformity and thus is suitable for covering a surface of an opening portion with a high aspect ratio, for example. Note that an ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gases. For example, by a CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a freely selected composition can be formed by concurrently introducing different kinds of precursors. In the case where different kinds of precursors are introduced, a film with a freely selected composition can be formed by controlling the number of cycles for each of the precursors.

First, a substrate (not illustrated) is prepared, and the insulator 212 is formed over the substrate.

The conductor 242 is formed over the insulator 212, and the insulator 270 is formed over the conductor 242 and the insulator 212. Note that the top surface of the insulator 270 is preferably flat. For example, the top surface of the insulator 270 is preferably planarized by performing CMP treatment after the insulator 270 is formed.

The conductor 260 is formed over the insulator 270, the conductor 244 is formed over the conductor 260, and the insulator 272 is formed over the conductor 260, the conductor 244, and the insulator 270 (FIG. 14A and FIG. 14B). Note that the top surface of the insulator 272 is preferably flat. For example, the top surface of the insulator 272 is preferably planarized by performing CMP treatment after the insulator 272 is formed.

The conductor 262 is formed over the insulator 272, and the insulator 274 is formed over the conductor 262 and the insulator 272 (FIG. 14C and FIG. 14D). Note that the top surface of the insulator 274 is preferably flat. For example, the top surface of the insulator 274 is preferably planarized by performing CMP treatment after the insulator 274 is formed.

Next, the insulator 270, the conductor 260, the insulator 272, the conductor 262, and the insulator 274 are processed by a lithography method and an etching method to form an opening 258a reaching the conductor 244 and an opening 258b reaching the conductor 242 (FIG. 14E and FIG. 14F). The opening 258a corresponds to the above-described first opening, and the opening 258b corresponds to the above-described second opening. Wet etching may be used for forming the opening 258a and the opening 258b; however, dry etching is preferably used for fine processing.

A material different from that for the conductor 260 is preferably used for the conductor 244, and an etching method with a high etching selectivity ratio of the conductor 260 to the conductor 244 is preferably selected. When the etching selectivity of the conductor 260 to the conductor 244 is high, the conductor 244 can function as an etching stop film during the formation of the opening 258a and the opening 258b. Thus, the opening 258a can be inhibited from having an excessively large depth.

Moreover, a material different from that for the conductor 262 is preferably used for the conductor 244, and an etching method with a high etching selectivity ratio of the conductor 262 to the conductor 244 is preferably selected. Furthermore, a material different from that for the conductor 260 is preferably used for the conductor 242, and an etching method with a high etching selectivity ratio of the conductor 260 to the conductor 242 is preferably selected. Thus, the opening 258a and the opening 258b can be formed under the same conditions. Accordingly, the manufacturing process of the semiconductor device can be simplified, and the productivity can be improved.

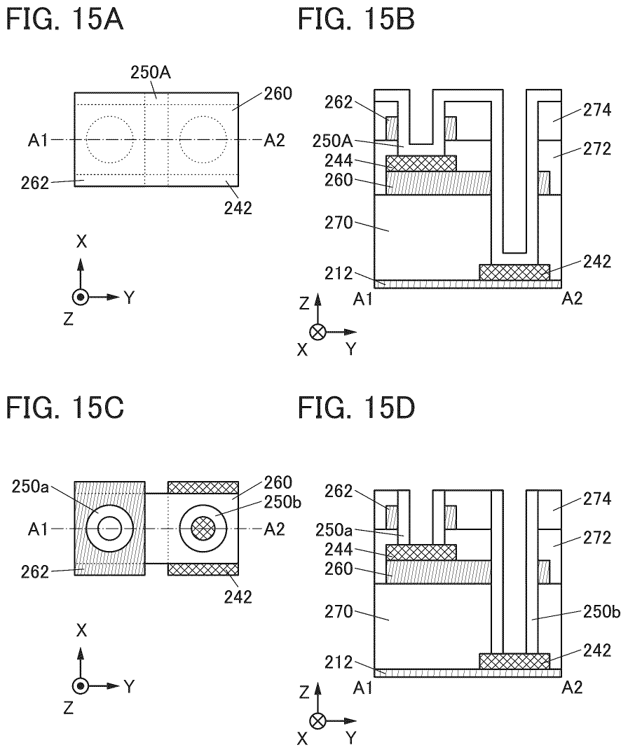

Next, an insulating film 250A is formed (FIG. 15A and FIG. 15B). The insulating film 250A is preferably formed by an ALD method. The insulator 250 is preferably formed to have a small thickness and a small variation in thickness. Since an ALD method is a film formation method in which a precursor and a reactant (e.g., oxidizer) are alternately introduced and the thickness can be adjusted with the number of repetition times of the cycle, accurate control of the thickness is possible. As illustrated in FIG. 15B, the insulating film 250A is preferably formed with good coverage on the bottom surfaces and the side surfaces of the opening 258a and the opening 258b. With use of an ALD method, an atomic layer can be deposited one by one on the bottom surfaces and the side surfaces of the opening 258a and the opening 258b. Thus, the insulator 250a and the insulator 250b can be formed with good coverage in the opening 258a and the opening 258b, respectively.

When the insulating film 250A is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the oxide 230 formed later can be reduced.

Next, the insulating film 250A is subjected to anisotropic etching to form the insulator 250a in contact with the side surfaces of the insulator 272, the conductor 262, and the insulator 274 in the opening 258a and form the insulator 250b in contact with the side surfaces of the insulator 270, the conductor 260, the insulator 272, and the insulator 274 in the opening 258b (FIG. 15C and FIG. 15D). For the anisotropic etching of the insulating film 250A, a dry etching method is employed, for example. The insulating film 250A is subjected to anisotropic etching, whereby part of the top surface of the conductor 242 and part of the top surface of the conductor 244 can be exposed.

Note that in the case where the insulator 254a and the insulator 254b illustrated in FIG. 7B are formed, after the opening 258a and the opening 258b are formed, it is preferable to form an insulating film to be the insulator 254a and the insulator 254b and the insulating film 250A sequentially and then perform the above anisotropic etching.

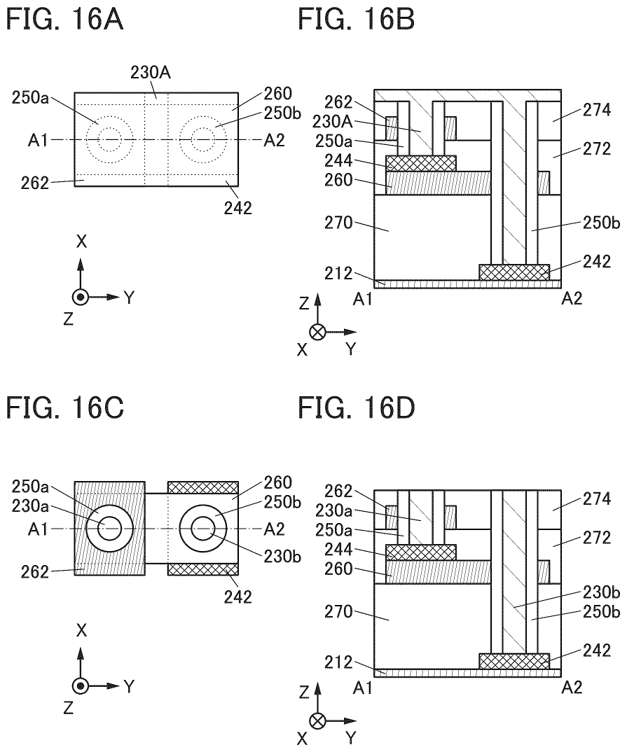

Next, an oxide film 230A is formed over the insulator 250a and the insulator 250b (FIG. 16A and FIG. 16B). The oxide film 230A is preferably formed by an ALD method. When an ALD method is employed, a film with a uniform thickness can be formed even in a groove or an opening portion having a high aspect ratio. When a PEALD method is employed, the oxide film 230A can be formed at a low temperature compared with the case of employing a thermal ALD method. Note that the oxide film 230A may be formed by a sputtering method.

Note that after the oxide film is formed by an ALD method, microwave treatment is preferably performed, and further preferably the microwave treatment is performed in an oxygen-containing atmosphere.

The microwave treatment performed in an oxygen-containing atmosphere converts an oxygen gas into plasma using a high-frequency wave such as a microwave or RF, so that the oxygen plasma can be applied to the oxide film. At this time, the oxide film can be irradiated with the high-frequency wave such as a microwave or RF. In other words, the high-frequency wave such as a microwave or RF, the oxygen plasma, and the like can be applied to the oxide film.

The effect of the high-frequency wave, the oxygen plasma, and the like can reduce the impurity concentration of the oxide film. For example, hydrogen in the oxide film can be released as a water molecule. Alternatively, carbon in the oxide film can be released as an oxocarbon (CO and/or CO₂), for example. In addition, by supply of oxygen radicals generated by the oxygen plasma to the oxide film, oxygen vacancies, VoH, or the like in the oxide film can be reduced.

The effect of the high-frequency wave, the oxygen plasma, and the like can apply energy which is higher than or equal to the treatment temperature of the microwave treatment to the atom in the oxide film. Thus, rearrangement of metal atoms and oxygen atoms in the oxide film is promoted, so that the crystallinity of the oxide film can be improved. Note that as the impurity concentration and the amount of defects (e.g., oxygen vacancies and VoH) in the oxide film are reduced, the crystallinity of the oxide film tends to be improved. That is, the microwave treatment in an oxygen-containing atmosphere reduces the impurity concentration and the amount of the defects in the oxide film and improves the crystallinity of the oxide film.

Next, CMP treatment is performed to remove part of the oxide film 230A, so that the insulator 274 is exposed. As a result, the oxide 230a is formed to fill the opening 258a, and the oxide 230b is formed to fill the opening 258b (FIG. 16C and FIG. 16D). Note that the insulator 274 is partly removed by the CMP treatment in some cases. This enables the insulator 274 to be planarized. In such a manner, the top surface of the oxide 230a, the top surface of the oxide 230b, the top surface of the insulator 250a, the top surface of the insulator 250b, and the top surface of the insulator 274 are made level with each other.

Note that in the case where the insulator 275 illustrated in FIG. 6B is formed, after the oxide film 230A is formed, it is preferable to form an insulating film to be the insulator 275 and then perform the above CMP treatment.

Note that the microwave treatment may be performed not after the oxide film 230A is formed but after the above CMP treatment is performed.

Next, the conductor 246 is formed over the oxide 230a, the oxide 230b, the insulator 250a, the insulator 250b, and the insulator 274. In the above manner, the memory cell 100 illustrated in FIG. 2A to FIG. 2D can be manufactured. Moreover, the semiconductor device including the memory cell 100 illustrated in FIG. 2A to FIG. 2D can be manufactured.

This embodiment can be combined with the other embodiments as appropriate. In this specification, in the case where a plurality of structure examples are described in one embodiment, the structure examples can be combined as appropriate.

### Embodiment 2

In this embodiment, a storage device of one embodiment of the present invention will be described with reference to drawings. The storage device of one embodiment of the present invention is a storage device including a transistor in which an oxide is used as a semiconductor (hereinafter referred to as an OS transistor in some cases) (hereinafter the storage device is referred to as an OS memory device in some cases).

### <Structure Example of Storage Device>

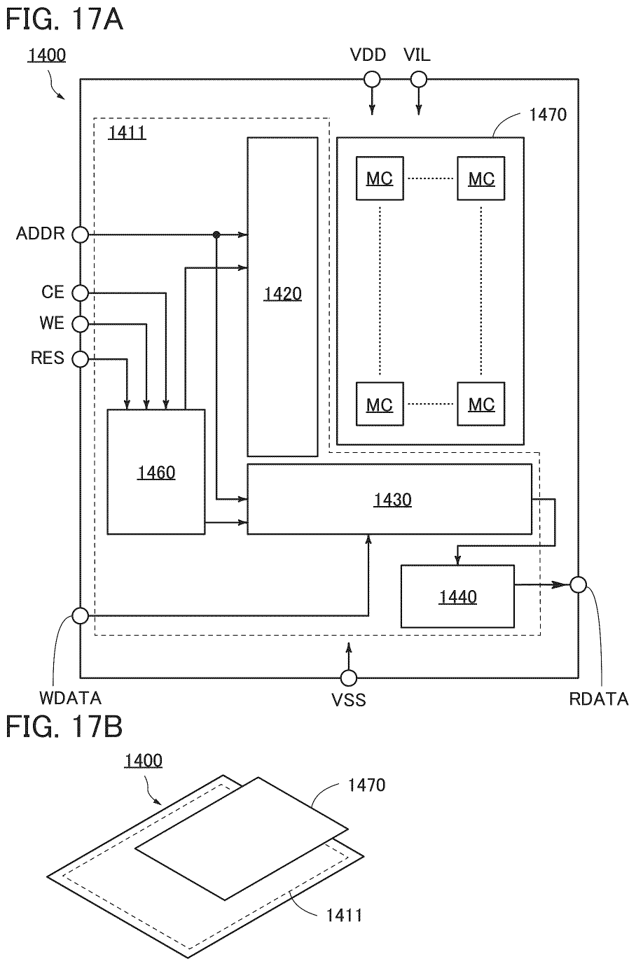

FIG. 17A illustrates a structure example of the OS memory device. A storage device 1400 includes a peripheral circuit 1411 and a memory cell array 1470. The peripheral circuit 1411 is a circuit having a function of writing data to a memory cell included in the memory cell array 1470 and reading data from the memory cell included in the memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RES), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RES) input from the outside, and generates control signals for the row decoder and the column decoder. The control signal CE is a chip enable signal, the control signal WE is a write enable signal, and the control signal RES is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 17A illustrates an example in which the peripheral circuit 1411 and the memory cell array 1470 are formed on the same plane; however, this embodiment is not limited thereto. For example, as illustrated in FIG. 17B, the memory cell array 1470 may be provided to overlap with part of the peripheral circuit 1411. For example, the sense amplifier may be provided below the memory cell array 1470 so that they overlap with each other.

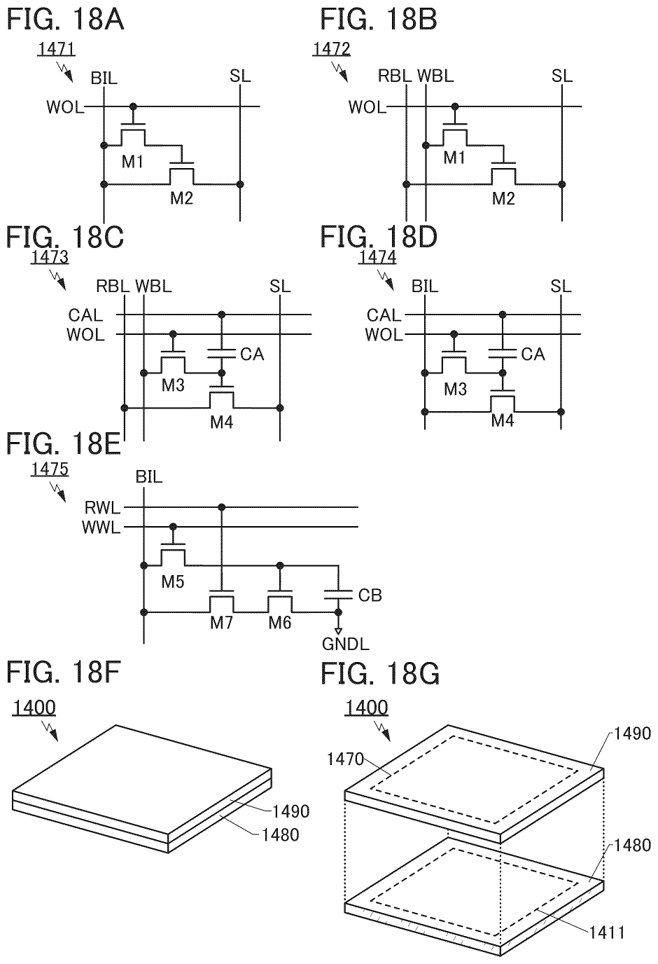

With FIG. 18A to FIG. 18E, structure examples of memory cells applicable to the memory cell MC are described.

FIG. 18A illustrates a circuit structure example of a gain-cell-type memory cell including two transistors. A memory cell 1471 illustrated in FIG. 18A includes a transistor M1 and a transistor M2. The transistor M1 and the transistor M2 are each a single-gate transistor.

A first terminal of the transistor M1 is connected to a gate of the transistor M2. A second terminal of the transistor M1 is connected to the wiring BIL. A gate of the transistor M1 is connected to the wiring WOL. A first terminal of the transistor M2 is connected to the wiring BIL. A second terminal of the transistor M2 is connected to the wiring SL.

The wiring BIL functions as a bit line, the wiring WOL functions as a word line, and the wiring SL functions as a selection line.

In the memory cell 1471, the gate capacitance of the transistor M2 is used as storage capacitance. That is, the memory cell 1471 can be regarded as a capacitor-less memory cell. Thus, the memory cell 1471 can be regarded as a gain-cell-type memory cell with two transistors and no capacitor.

When the OS transistor is used as the transistor M1 and the transistor M1 is turned off, charge at a node where one of a source and a drain of the transistor M1 is electrically connected to the gate of the transistor M2 can be retained for an extremely long time. Accordingly, a nonvolatile memory cell can be obtained.

As the memory cell 1471 illustrated in FIG. 18A, the memory cell 100 illustrated in FIG. 2A to FIG. 2D or the like can be used. In this case, the transistor M1 and the transistor M2 correspond to the transistor 200a and the transistor 200b, respectively. The wiring BIL, the wiring WOL, and the wiring SL correspond to the conductor 246, the conductor 262, and the conductor 242, respectively.

FIG. 18B illustrates another circuit structure example of a gain-cell-type memory cell including two transistors. A memory cell 1472 illustrated in FIG. 18B includes the transistor M1 and the transistor M2. The transistor M1 and the transistor M2 are each a single-gate transistor.

The first terminal of the transistor M1 is connected to the gate of the transistor M2. The second terminal of the transistor M1 is connected to the wiring WBL. The gate of the transistor M1 is connected to the wiring WOL. The first terminal of the transistor M2 is connected to the wiring RBL. The second terminal of the transistor M2 is connected to the wiring SL.

The wiring WBL functions as a write bit line, and the wiring RBL functions as a read bit line.

In the memory cell 1472, the gate capacitance of the transistor M2 is used as storage capacitance, as in the memory cell 1471. When the OS transistor is used as the transistor M1 and the transistor M1 is turned off, charge at a node where one of the source and the drain of the transistor M1 is electrically connected to the gate of the transistor M2 can be retained for an extremely long time. Accordingly, a nonvolatile memory cell can be obtained.

As the memory cell 1472 illustrated in FIG. 18B, the memory cell 100A illustrated in FIG. 9A to FIG. 9D can be used. In this case, the transistor M1 and the transistor M2 correspond to the transistor 200a and the transistor 200b, respectively. The wiring WBL, the wiring RBL, the wiring WOL, and the wiring SL correspond to the conductor 246a, the conductor 246b, the conductor 262, and the conductor 242, respectively.

The circuit structure of the memory cell MC is not limited to that of the memory cell 1471 or the memory cell 1472 and can be changed as appropriate. For example, the transistor M1 and the transistor M2 may each include a back gate. In the case where the transistor M1 includes a back gate, the back gate may be electrically connected to the gate of the transistor M1, or may be electrically connected to a wiring for applying a potential to the back gate. The same applies to the case where the transistor M2 includes a back gate.

### [NOSRAM]

FIG. 18C and FIG. 18D each illustrate a circuit structure example of a gain-cell-type memory cell including two transistors and one capacitor. A memory cell 1473 illustrated in FIG. 18C includes a transistor M3, a transistor M4, and a capacitor CA. The transistor M3 and the transistor M4 are each a single-gate transistor. In this specification and the like, a storage device including a gain-cell-type memory cell using an OS transistor as at least the transistor M3 is referred to as a NOSRAM (Nonvolatile Oxide Semiconductor RAM) in some cases.

A first terminal of the transistor M3 is connected to a first terminal of the capacitor CA. A second terminal of the transistor M3 is connected to the wiring WBL. A gate of the transistor M3 is connected to the wiring WOL. A second terminal of the capacitor CA is connected to the wiring CAL. A first terminal of the transistor M4 is connected to the wiring RBL. A second terminal of the transistor M4 is connected to the wiring SL. A gate of the transistor M4 is connected to the first terminal of the capacitor CA.

The wiring CAL functions as a wiring for applying a predetermined potential to the second terminal of the capacitor CA. At the time of data writing and data reading, a high-level potential is preferably applied to the wiring CAL. During data retaining, a low-level potential is preferably applied to the wiring CAL.

The circuit structure of the memory cell MC is not limited to that of the memory cell 1473 and can be changed as appropriate. For example, in the memory cell MC, the wiring WBL and the wiring RBL may be combined into one wiring BIL, as in a memory cell 1474 illustrated in FIG. 18D. Alternatively, for example, the transistor M3 may include a back gate. In the case where the transistor M3 includes a back gate, the back gate may be electrically connected to the gate of the transistor M3, or may be electrically connected to a wiring for applying a potential to the back gate.

In the case where the semiconductor device described in the above embodiment is used in the memory cell 1473 and the like, the transistor 200 can be used as the transistor M3. When an OS transistor is used as the transistor M3, the leakage current of the transistor M3 can be extremely low. Accordingly, with use of the transistor M3, written data can be retained for a long time, and thus the frequency of the refresh operation for the memory cell can be decreased. Alternatively, a refresh operation for the memory cell can be unnecessary. In addition, since the OS transistor has an extremely low leakage current, multi-level data or analog data can be retained in the memory cell 1473. The same applies to the memory cell 1474.

Moreover, an OS transistor can be used as the transistor M4. For example, the transistor 200a can be used as the transistor M3, and the transistor 200b or the double-gate transistor 200c can be used as the transistor M4. When an OS transistor is used as each of the transistor M3 and the transistor M4, the circuit of the memory cell array 1470 can be formed using only n-type transistors.

As the memory cell 1473 illustrated in FIG. 18C, the memory cell 100C illustrated in FIG. 12A to FIG. 12D can be used. In this case, the transistor M3 and the transistor M4 correspond to the transistor 200a and the transistor 200b, respectively. The wiring WBL, the wiring RBL, the wiring WOL, the wiring SL, and the wiring CAL correspond to the conductor 246a, the conductor 246b, the conductor 262, the conductor 242b, and the conductor 242c, respectively.

As the memory cell 1474 illustrated in FIG. 18D, the memory cell 100B illustrated in FIG. 10A to FIG. 10D or the like can be used. In this case, the transistor M3 and the transistor M4 correspond to the transistor 200a and the transistor 200b, respectively. The wiring BIL, the wiring WOL, the wiring SL, and the wiring CAL correspond to the conductor 246, the conductor 262, the conductor 242b, and the conductor 242c, respectively.

Note that the transistor M4 may be a transistor including silicon in a channel formation region (hereinafter, sometimes referred to as a Si transistor). A Si transistor may be either an n-channel transistor or a p-channel transistor. A Si transistor has higher field-effect mobility than an OS transistor in some cases. Therefore, a Si transistor may be used as the transistor M4 functioning as a read transistor. Furthermore, the transistor M3 can be stacked over the transistor M4 when a Si transistor is used as the transistor M4, in which case the area occupied by the memory cell can be reduced, leading to high integration of the storage device.

FIG. 18E illustrates an example of a gain-cell-type memory cell including three transistors and one capacitor. A memory cell 1475 illustrated in FIG. 18E includes a transistor M5 to a transistor M7 and a capacitor CB. The capacitor CB is provided as appropriate. The memory cell 1475 is electrically connected to the wiring BIL, the wiring RWL, the wiring WWL, and the wiring GNDL. The wiring GNDL is a wiring supplying a low-level potential. Note that the memory cell 1475 may be electrically connected to the wiring RBL and the wiring WBL instead of the wiring BIL.

The transistor M5 is a single-gate OS transistor. The transistor M5 may include a back gate. In the case where the transistor M5 includes a back gate, the back gate may be electrically connected to a gate of the transistor M5, or may be electrically connected to a wiring for applying a potential to the back gate.

In the case where the semiconductor device described in the above embodiment is used in the memory cell 1475, the transistor 200 can be used as the transistor M5. When an OS transistor is used as the transistor M5, the leakage current of the transistor M5 can be extremely low.

Moreover, OS transistors can be used as the transistor M5 to the transistor M7. For example, the transistor 200a can be used as the transistor M5, and the transistor 200c having a structure in which two transistors are connected in series can be used as each of the transistor M6 and the transistor M7. In this case, the circuit of the memory cell array 1470 can be formed using only n-type transistors. Note that each of the transistor M6 and the transistor M7 may be an n-channel Si transistor or a p-channel Si transistor.

As the memory cell 1475 illustrated in FIG. 18E, the memory cell 100D illustrated in FIG. 13A to FIG. 13D can be used. In this case, the transistor M5, the transistor M6, and the transistor M7 correspond to the transistor 200a, one of the two transistors connected in series, and the other of the two transistors connected in series, respectively. The wiring BIL, the wiring WWL, the wiring RWL, and the wiring GNDL correspond to the conductor 246, the conductor 262a, the conductor 262c, and the conductor 242, respectively.

The circuit structure of the memory cell MC is not limited to those of the memory cell 1471 to the memory cell 1475 and can be changed.

When an OS transistor is used as the transistor M1, the transistor M1 can be formed in a BEOL (Back end of line) process for forming a wiring of the storage device. In the case where a Si transistor is used in the peripheral circuit 1411 that is below and overlaps with the memory cell array 1470, technology for forming an OS transistor directly above the Si transistor (referred to as BEOL-Tr technology) can be employed. With this technology, a 3D functional circuit can be constructed without a change in a design rule, and high functionality can be achieved with low power consumption and low cost.

FIG. 18F is a perspective view of the storage device 1400. The storage device 1400 includes a layer 1480 and a layer 1490. FIG. 18G is a perspective view for explaining the structure of the storage device 1400, illustrating the layer 1480 and the layer 1490 separately.

The layer 1480 is a layer including a transistor. A semiconductor layer including a channel formation region of the transistor is formed using a semiconductor material such as a single crystal semiconductor, a polycrystalline semiconductor, a microcrystalline semiconductor, or an amorphous semiconductor alone or in combination. As the semiconductor material, silicon, germanium, or the like can be used. Alternatively, a compound semiconductor such as silicon germanium, silicon carbide, gallium arsenide, an oxide semiconductor, or a nitride semiconductor may be used. Alternatively, gallium arsenide, aluminum gallium arsenide, indium gallium arsenide, gallium nitride, indium phosphide, silicon germanium, or the like that can be used for a HEMT (High Electron Mobility Transistor) may be used.

The layer 1490 is a layer including a transistor. A semiconductor layer including a channel formation region of the transistor is formed using a semiconductor material enabling formation of a thin film, such as an oxide semiconductor or silicon. With use of the BEOL-Tr technology, the layer 1490 can be provided over the layer 1480. Thus, miniaturization of the storage device 1400 can be achieved.

For example, the transistor included in the layer 1480 is a Si transistor. In this case, the peripheral circuit 1411 can be provided in the layer 1480. The transistor included in the layer 1490 is an OS transistor. In this case, the memory cell array 1470 can be provided in the layer 1480.

Accordingly, the storage device 1400 can be manufactured with use of the BEOL-Tr technology. Thus, the area occupied by the storage device 1400 can be reduced.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed.

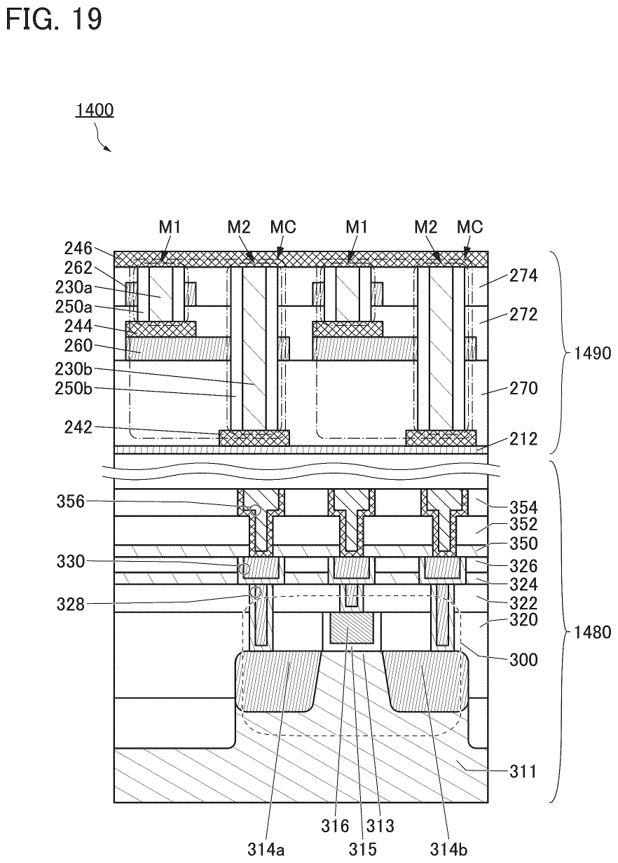

FIG. 19 illustrates a cross-sectional structure example of the storage device 1400 illustrated in FIG. 17A. In FIG. 19, part of the storage device 1400 illustrated in FIG. 17A is shown.

As illustrated in FIG. 19, the storage device 1400 includes the layer 1480 and the layer 1490 over the layer 1480. The peripheral circuit 1411 is provided in the layer 1480. That is, the layer 1480 can be regarded as a layer including the peripheral circuit 1411. In addition, the memory cell array 1470 is provided in the layer 1490. The semiconductor device described in the above embodiment can be used for the memory cell included in the memory cell array 1470. That is, the layer 1480 is positioned below the semiconductor device described in the above embodiment.

FIG. 19 illustrates a transistor 300 included in the layer 1480. The transistor 300 functions as part of the above-described sense amplifier. In this case, the layer 1480 can be regarded as a substrate where a semiconductor circuit including a transistor is formed.

FIG. 19 illustrates part of the memory cell array 1470 provided in the layer 1490. Specifically, FIG. 19 illustrates two memory cells MC provided in the layer 1490.

The conductor 262 corresponds to the wiring WOL. The conductor 244 corresponds to the wiring BIL. The conductor 246 corresponds to the wiring SL.

Although FIG. 19 illustrates the structure provided with one layer 1490 including the memory cell array 1470, the present invention is not limited thereto. For example, a plurality of layers each including the memory cell array 1470 may be stacked.

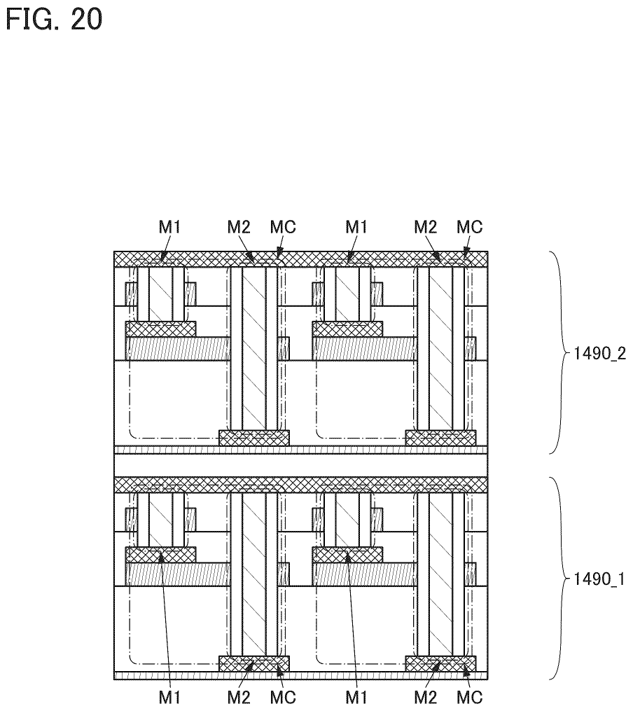

FIG. 20 illustrates a structure in which a layer 1490_1 including a memory cell array and a layer 14902 including a memory cell array are stacked. Note that the number of stacked layers may be three or more. When an OS transistor is used as a transistor included in the memory cell 100, a plurality of memory cell arrays 1470 can be stacked in such a manner. That is, the amount of data that can be stored per unit area can be increased.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 19, the semiconductor region 313 (part of the substrate 311) in which the channel is formed has a protruding shape. In addition, the conductor 316 is provided to cover the side surface and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 19 is an example and the structure is not limited thereto; an appropriate transistor is used in accordance with a circuit structure or a driving method.

### <Wiring Layer>

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 300 as interlayer films. A conductor 328, a conductor 330, and the like that are electrically connected to the transistor 200 are embedded in the insulator 320, the insulator 322, the insulator 324, and the insulator 326. Note that the conductor 328 and the conductor 330 function as a plug or a wiring.

The insulators functioning as interlayer films may also function as planarization films that cover uneven shapes therebelow. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 19, an insulator 350, an insulator 352, and an insulator 354 are sequentially stacked. Furthermore, the conductor 356 is formed in the insulator 350, the insulator 352, and the insulator 354. The conductor 356 functions as a plug or a wiring.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low relative permittivity is used for the insulator functioning as an interlayer film, parasitic capacitance generated between wirings can be reduced. Thus, a material is preferably selected depending on the function of an insulator.

For example, as the insulator 322, the insulator 352, the insulator 354, and the like, an insulator having a low relative permittivity is preferably used. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

When a transistor including an oxide semiconductor is surrounded by an insulator having a function of inhibiting passage of oxygen and impurities such as hydrogen, the electrical characteristics of the transistor can be stable. Thus, the insulator having a function of inhibiting the passage of oxygen and impurities such as hydrogen is used for the insulator 350 and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 356, and the like, a single-layer structure or a stacked-layer structure using a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

This embodiment can be combined with the other embodiments as appropriate. In this specification, in the case where a plurality of structure examples are described in one embodiment, the structure examples can be combined as appropriate.

### Embodiment 3

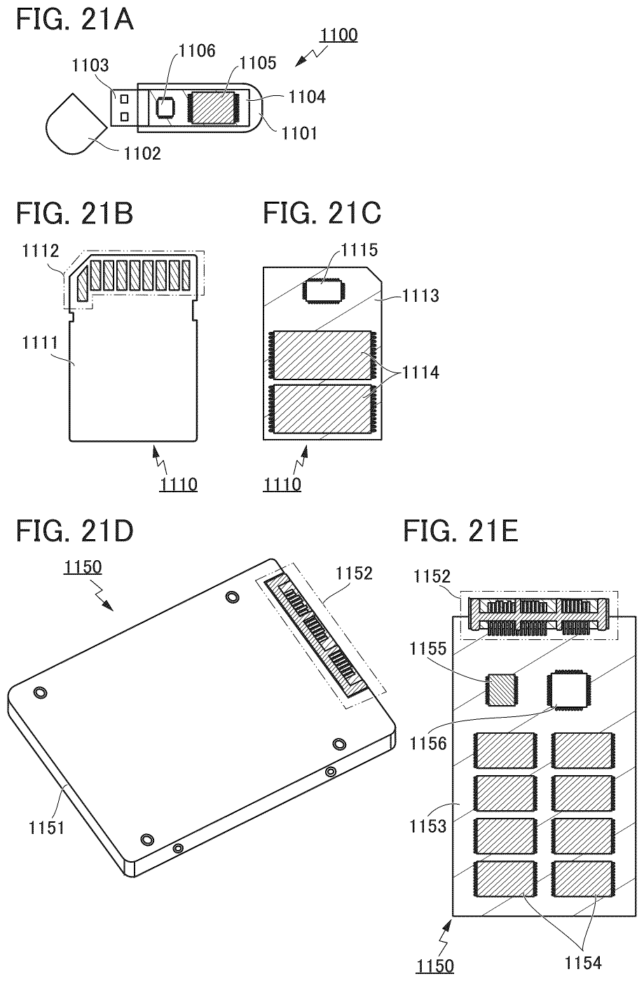

In this embodiment, application examples of the semiconductor device using the storage device described in the above embodiment will be described. The storage device described in the above embodiment can be applied to, for example, a variety of removable storage devices such as memory cards (e.g., SD cards), USB memories, and SSDs (solid state drives). FIG. 21A to FIG. 21E schematically illustrate some structure examples of removable storage devices. The semiconductor device described in the above embodiment is processed into a packaged memory chip and used in a variety of storage devices and removable memories, for example.

FIG. 21A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The storage device or the semiconductor device described in the above embodiment can be incorporated in the memory chip 1105 or the like.

FIG. 21B is a schematic external view of an SD card, and FIG. 21C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The storage device or the semiconductor device described in the above embodiment can be incorporated in the memory chip 1114 or the like.

FIG. 21D is a schematic external view of an SSD, and FIG. 21E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip is used, for example. When the memory chip 1154 is also provided on the back side of the substrate 1153, the capacity of the SSD 1150 can be increased. The storage device or the semiconductor device described in the above embodiment can be incorporated in the memory chip 1154 or the like.

This embodiment can be implemented in an appropriate combination with the structures described in the other embodiments and the like.

### Embodiment 4

In this embodiment, a transistor whose channel formation region includes an oxide semiconductor (OS transistor) is described. In the description of the OS transistor, comparison with a transistor whose channel formation region includes silicon (also referred to as Si transistor) is also described briefly.

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is also preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

If impurities and oxygen vacancies exist in a channel formation region in an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as V_{O}H) may be formed and may generate an electron serving as a carrier. When V_{O}H is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (characteristics with which a channel exists and a current flows through the transistor even when no voltage is applied to the gate electrode). Thus, impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in an OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometime also referred to as S value), and an increase in leakage current. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for a Si transistor to have a gate length less than or equal to 20 nm or less than or equal to 15 nm because of appearance of a short-channel effect. Therefore, an OS transistor can be suitably used as a transistor having a short channel length as compared with a Si transistor. Note that the gate length refers to the length of a gate electrode in a direction in which carriers move inside a channel formation region during an operation of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

The configurations, structures, methods, and the like described in this embodiment can be used in an appropriate combination with any of the configurations, structures, methods, and the like described in the other embodiments and the like.

### Embodiment 5

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

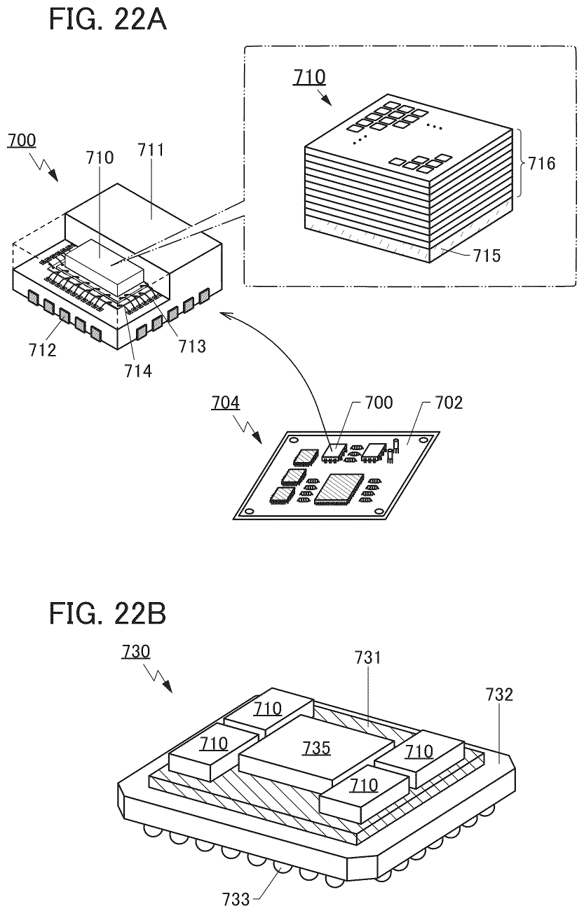

FIG. 22A is a perspective view of a substrate (a circuit board 704) on which an electronic component 700 is mounted. The electronic component 700 illustrated in FIG. 22A includes a semiconductor device 710 in a mold 711. Some components are omitted in FIG. 22A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 22B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU, a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 22B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

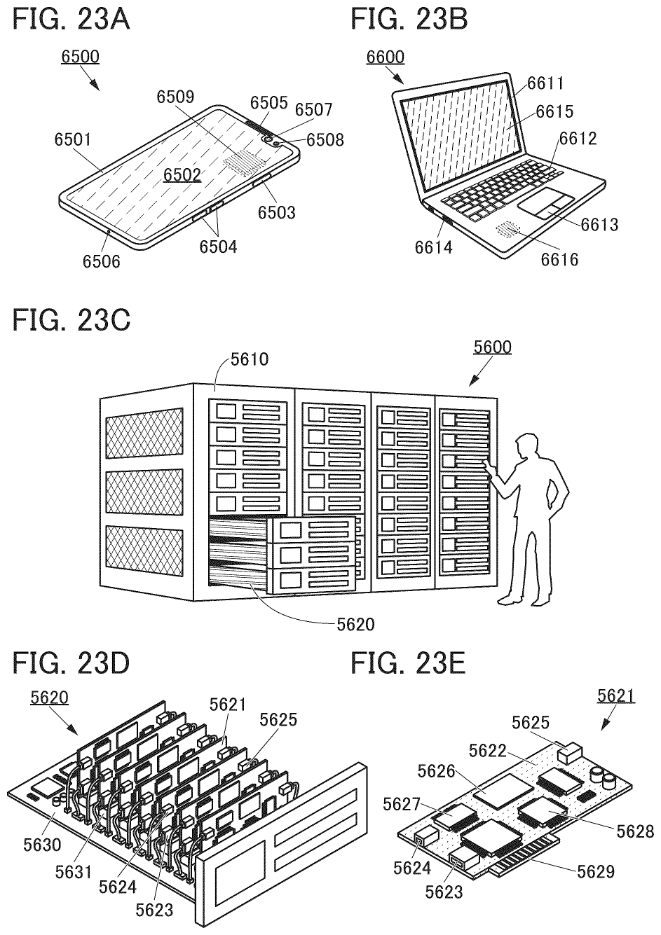

FIG. 23A is a perspective view of an electronic device 6500. The electronic device 6500 illustrated in FIG. 23A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a storage device are provided as the control device 6509, for example. The semiconductor device of one embodiment of the present invention can be used for the display portion 6502, the control device 6509, and the like.

An electronic device 6600 illustrated in FIG. 23B is an information terminal that can be used as a notebook personal computer. The electronic device 6600 includes a housing 6611, a keyboard 6612, a pointing device 6613, an external connection port 6614, a display portion 6615, a control device 6616, and the like. One or more selected from a CPU, a GPU, and a storage device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 23C is a perspective view of a large computer 5600. In the large computer 5600 illustrated in FIG. 23C, a plurality of rack mount computers 5620 are stored in a rack 5610. Note that the large computer 5600 may be referred to as a supercomputer.

The computer 5620 can have a structure in a perspective view of FIG. 23D, for example. In FIG. 23D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 23E is an example of a processing board provided with a CPU, a GPU, a storage device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 23E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

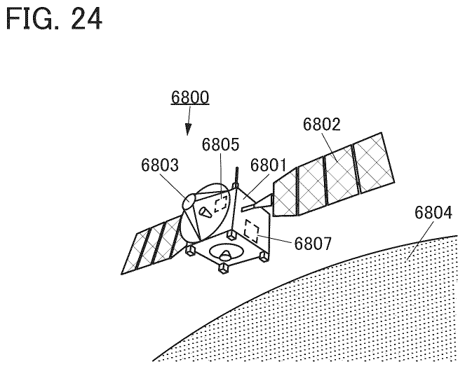

FIG. 24 illustrates an artificial satellite 6800 as an example of space equipment. The artificial satellite 6800 includes a body 6801, a solar panel 6802, an antenna 6803, a secondary battery 6805, and a control device 6807. FIG. 24 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 24, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. One or more selected from a CPU, a GPU, and a storage device are used as the control device 6807, for example. Note that the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system in a data center, for example. Long-term management of data, such as guarantee of data immutability, is required for the data center. The management of long-term data needs an increase in building size owing to installation of storages and servers for storing an enormous amount of data, stable electric power for data retention, cooling equipment necessary for data retention, and the like.

With the use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved. This can reduce the space of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high-temperature environment. Thus, the reliability of the data center can be increased.

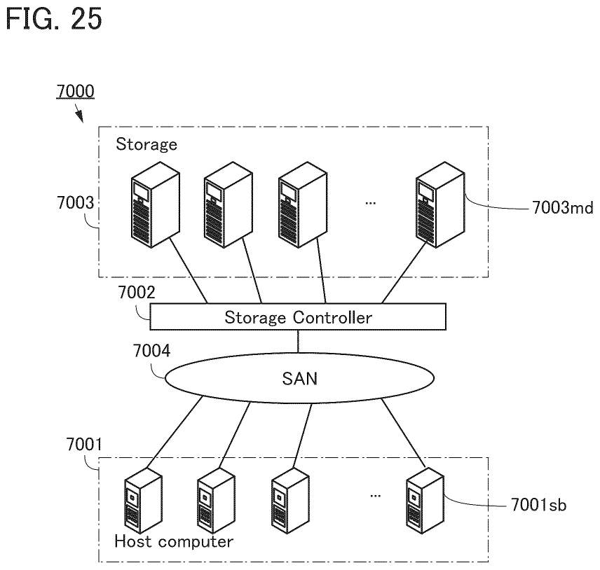

FIG. 25 illustrates a storage system that can be used in a data center. A storage system 7000 illustrated in FIG. 25 includes a plurality of servers 7001sb as a host 7001 (indicated as “Host Computer” in the diagram). The storage system 7000 includes a plurality of storage devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

The configurations, structures, methods, and the like described in this embodiment can be used in an appropriate combination with any of the configurations, structures, methods, and the like described in the other embodiments and the like.

### REFERENCE NUMERALS

ADDR address signal
BIL: wiring, CA: capacitor, CAL: wiring, CB: capacitor, CE: control signal, GNDL: wiring, MC: memory cell, RBL: wiring, RDATA: data signal, RES: control signal, RWL: wiring, SL: wiring, WBL: wiring, WDATA: data signal, WE: control signal, WOL: wiring, WWL: wiring, 10: semiconductor device, 100A: memory cell, 100B: memory cell, 100C: memory cell, 100D: memory cell, 100: memory cell, 200a: transistor, 200b: transistor, 200c: transistor, 200c1: transistor, 200c2: transistor, 200: transistor, 201: capacitor, 212: insulator, 230a: oxide, 230A: oxide film, 230b: oxide, 230: oxide, 242b: conductor, 242c: conductor, 242: conductor, 243: conductor, 244: conductor, 246a: conductor, 246b: conductor, 246: conductor, 250a: insulator, 250A: insulating film, 250b: insulator, 250: insulator, 254a: insulator, 254b: insulator, 258a: opening, 258b: opening, 260: conductor, 261: insulator, 262a: conductor, 262c: conductor, 262: conductor, 263: insulator, 270: insulator, 271: insulator, 272: insulator, 274: insulator, 275: insulator, 281: insulator, 282: insulator, 283: insulator, 284: insulator, 285: insulator, 286: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1400: storage device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1480: layer, 1490_1: layer, 1490_2: layer, 1490: layer, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: storage device, 7003: storage

1. A semiconductor device comprising:
a first conductor;
a first insulator over the first conductor;
a second conductor over the first insulator;
a third conductor over the second conductor;
a second insulator over the first insulator, the second conductor, and the third conductor;
a fourth conductor over the second insulator;
a third insulator over the fourth conductor;
a fifth conductor over the third insulator;
a first oxide;
a second oxide;
a fourth insulator; and
a fifth insulator,
wherein a first opening reaching the third conductor is provided in the second insulator, the fourth conductor, and the third insulator,
wherein the fourth insulator comprises a region in contact with a side surface of the fourth conductor in the first opening,
wherein the first oxide comprises a region facing the fourth conductor with the fourth insulator therebetween, a region in contact with at least part of a top surface of the third conductor, and a region in contact with at least part of a bottom surface of the fifth conductor,
wherein a second opening reaching the first conductor is provided in the first insulator, the second conductor, the second insulator, and the third insulator,
wherein the fifth insulator comprises a region in contact with a side surface of the second conductor in the second opening, and
wherein the second oxide comprises a region facing the second conductor with the fifth insulator therebetween, a region in contact with at least part of a top surface of the first conductor, and a region in contact with at least part of the bottom surface of the fifth conductor.

2. The semiconductor device according to claim 1,
wherein a direction in which the fourth conductor extends is parallel to a direction in which the first conductor extends.

3. The semiconductor device according to claim 1,
wherein a diameter of the second opening is larger than a diameter of the first opening in a plan view.

4. The semiconductor device according to claim 1,
wherein a sidewall of the first opening and a sidewall of the second opening each comprise a tapered shape in a cross-sectional view.

5. A semiconductor device comprising:
a first insulator;
a first conductor and a second conductor over the first insulator;
a second insulator over the first insulator, the first conductor, and the second conductor;
a third conductor over the second insulator;
a fourth conductor over the third conductor;
a third insulator over the second insulator, the third conductor, and the fourth conductor;
a fifth conductor over the third insulator;
a fourth insulator over the fifth conductor;
a sixth conductor over the fourth insulator;
a first oxide;
a second oxide;
a fifth insulator; and
a sixth insulator,
wherein the first conductor comprises a region overlapping with the third conductor with the second insulator therebetween,
wherein a first opening reaching the fourth conductor is provided in the third insulator, the fifth conductor, and the fourth insulator,
wherein the fifth insulator comprises a region in contact with a side surface of the fifth conductor in the first opening,
wherein the first oxide comprises a region facing the fifth conductor with the fifth insulator therebetween, a region in contact with at least part of a top surface of the fourth conductor, and a region in contact with at least part of a bottom surface of the sixth conductor,
wherein a second opening reaching the second conductor is provided in the second insulator, the third conductor, the third insulator, and the fourth insulator,
wherein the sixth insulator comprises a region in contact with a side surface of the third conductor in the second opening, and
wherein the second oxide comprises a region facing the third conductor with the sixth insulator therebetween, a region in contact with at least part of a top surface of the second conductor, and a region in contact with at least part of the bottom surface of the sixth conductor.

6. The semiconductor device according to claim 5,
wherein a direction in which the first conductor extends is parallel to a direction in which the second conductor extends, and
wherein a direction in which the fifth conductor extends is parallel to the direction in which the second conductor extends.

7. The semiconductor device according to claim 5,
wherein the first conductor and the second conductor are provided in the same layer.

8. A semiconductor device comprising:
a first insulator;
a first conductor and a second conductor over the first insulator;
a second insulator over the first insulator, the first conductor, and the second conductor;
a third conductor over the second insulator;
a fourth conductor over the third conductor;
a third insulator over the second insulator, the third conductor, and the fourth conductor;
a fifth conductor over the third insulator;
a fourth insulator over the fifth conductor;
a sixth conductor and a seventh conductor over the fourth insulator;
a first oxide;
a second oxide;
a fifth insulator; and
a sixth insulator,
wherein the first conductor comprises a region overlapping with the third conductor with the second insulator therebetween,
wherein a first opening reaching the fourth conductor is provided in the third insulator, the fifth conductor, and the fourth insulator,
wherein the fifth insulator comprises a region in contact with a side surface of the fifth conductor in the first opening,
wherein the first oxide comprises a region facing the fifth conductor with the fifth insulator therebetween, a region in contact with at least part of a top surface of the fourth conductor, and a region in contact with at least part of a bottom surface of the sixth conductor,
wherein a second opening reaching the second conductor is provided in the second insulator, the third conductor, the third insulator, and the fourth insulator,
wherein the sixth insulator comprises a region in contact with a side surface of the third conductor in the second opening, and
wherein the second oxide comprises a region facing the third conductor with the sixth insulator therebetween, a region in contact with at least part of a top surface of the second conductor, and a region in contact with at least part of a bottom surface of the seventh conductor.

9. The semiconductor device according to claim 8,
wherein a direction in which the first conductor extends is parallel to a direction in which the second conductor extends,
wherein a direction in which the fifth conductor extends is parallel to the direction in which the second conductor extends, and
wherein a direction in which the sixth conductor extends is parallel to a direction in which the seventh conductor extends.

10. The semiconductor device according to claim 8,
wherein the first conductor and the second conductor are provided in the same layer, and
wherein the sixth conductor and the seventh conductor are provided in the same layer.
